(19) United States
(12) Patent Application Publication
(10) Pub. No.: US 2014/0346480 A1
(43) Pub. Date: Nov. 27, 2014

(54) LIGHT EMITTING ELEMENT, DISPLAY APPARATUS, AND LIGHTING APPARATUS

(71) Applicant: Sony Corporation, Tokyo (JP)

(72) Inventors: Toshihiro FUKUDA, Kanagawa (JP); Kohji HANAWA, Kanagawa (JP)

(73) Assignee: Sony Corporation, Tokyo (JP)

(21) Appl. No.: 14/278,757

(22) Filed: May 15, 2014

(30) Foreign Application Priority Data
May 24, 2013 (JP) 2013-110214

(51) Int. Cl. H01L 51/50; H01L 51/52

(52) U.S. Cl. CPC H01L 51/5036; H01L 51/5271
USPC 257/40

(57) ABSTRACT

A light emitting element includes a first electrode, a second electrode, and an organic layer in which a first luminescent layer and a second luminescent layer are provided from a first electrode side, the organic layer being provided between the first electrode and the second electrode, light from the organic layer being reflected on an interface of the luminescent layer and the first electrode, passing through the second electrode, and being emitted to outside, a first optical transparent layer, a second optical transparent layer, and a third optical transparent layer being provided, from a second luminescent layer side, on a side of the second luminescent layer, the side being opposite to the first luminescent layer.

### CROSS REFERENCES TO RELATED APPLICATIONS

The present application claims priority to Japanese Priority Patent Application JP 2013-110214 filed in the Japan Patent Office on May 24, 2013, the entire content of which is hereby incorporated by reference.

### BACKGROUND

The present disclosure relates to a light emitting element and to a display apparatus and a lighting apparatus that use the light emitting element.

An organic electroluminescence element (hereinafter, referred to as “organic EL element”) attracts attention as a light emitting element that is capable of emitting high-luminance light with low voltage direct current driving, and research and development thereof has been actively carried out. The organic EL element generally has a structure in which an organic layer including a luminescent layer having a thickness of about several ten nm to several hundred nm is sandwiched between a reflective electrode and a translucent electrode. Then, light emitted from the luminescent layer is taken out to the outside. Attempts have been made to improve the light emission efficiency of the organic EL element using the interference of light in the element structure. Moreover, an organic EL element having a laminated structure in which a plurality of luminescent layers are sort of connected in series (so-called tandem structure) in order to improve the light emission efficiency and increase the light emission period, by laminating the plurality of luminescent layers via a connection layer, is also known. In such an organic EL element, arbitrary number of luminescent layers can be laminated. For example, by laminating a blue luminescent layer that generates blue light, a green luminescent layer that generates green light, and a red luminescent layer that generates red light, white light can be generated as combined light of the blue light, the green light, and the red light.

An organic EL element having such a configuration is known from, for example, Japanese Patent Application Laid-open No. 2011-159432. The organic EL element disclosed in Japanese Patent Application Laid-open No. 2011-159432 includes an organic layer successively including a first luminescent layer and a second luminescent layer at positions distant from each other in a direction from the first electrode to the second electrode, which are sandwiched between a first electrode and a second electrode and emit light of a color or two or more different colors in a visible light region, a first reflection interface that reflects light emitted from the first luminescent layer and the second luminescent layer, causes the reflected light to be emitted from a second electrode side, and is provided on a first electrode side, and a second reflection interface and a third reflection interface successively provided, on the second electrode side, at positions distant from each other in a direction from the first electrode side to the second electrode side, in which in a case where an optical distance between the first reflection interface and a light emission center of the first luminescent layer is assumed to be L₁₁, an optical distance between the first reflection interface and a light emission center of the second luminescent layer is assumed to be L₂₁, an optical distance between a light emission center of the first luminescent layer and the second reflection interface is assumed to be L₁₂, an optical distance between a light emission center of the second luminescent layer and the second reflection interface is assumed to be L₂₂, an optical distance between a light emission center of the first luminescent layer and the third reflection interface is assumed to be L₁₃, an optical distance between a light emission center of the second luminescent layer and the third reflection interface is assumed to be L₂₃, a central wavelength of light emission spectrum of the first luminescent layer is assumed to be 1, and a central wavelength of light emission spectrum of the second luminescent layer is assumed to be λ₂, L₁₁, L₂₁, L₁₂, L₂₂, L₁₃, and L₂₃ satisfy the following equations (1) to (6) and at least one of equations (7) and (8):

2L₁₁/λ₁₁+φ₁/2π=0 (1)

2L₂₁/λ₂₁+φ₁/2π=n (where n≧1) (2)

λ₁−150<λ₁₁<λ₁+80 (3)

λ₂−30<λ₂₁<₂+80 (4)

2L₁₂/λ₁₂+φ₂/2π=m′+½ and 2L₁₃/λ₁₃+φ₃/2π=m″ or 2L₁₂/λ₁₂+φ₂/2π=m′ and 2L₁₃/λ₁₃+φ₃/2π=m″+½ (5)

2L₂₂/λ₂₂+φ₂/2π=n′+½ and 2L₂₃/λ₂₃+φ₃/2π=n″ or 2L₂₂/λ₂₂+φ₂/2π=n′ and 2L₂₃/λ₂₃+φ₃/2π=n″+½ or 2L₂₂/λ₂₂+φ₂/2π=n′+½ and 2L₂₃/λ₂₃+φ₃/2π=n″+½ (6)

λ₂₂<λ2−15 or λ₂₃>λ₂+15 (7)

λ₂₃<λ2−15 or λ₂₂>λ₂+15 (8)

where m′, m″, n, n′, n″ are each an integer,

the unit of λ₁, λ₂, λ₁₁, λ₂₁, λ₁₂, λ₂₂, λ₁₃, λ₂₃ is nm,

φ₁ represents a phase change when light of each wavelength is reflected on the first reflection interface,

φ₂ represents a phase change when light of each wavelength is reflected on the second reflection interface,

φ₃ represents a phase change when light of each wavelength is reflected on the third reflection interface.

Then, by adopting such a configuration, it is possible to achieve a light emitting element that is capable of taking out light satisfactorily in a wide wavelength band and reducing the viewing angle dependency of luminance and chromaticity with respect to light of a color or combined colors of two or more different colors in the visible light region significantly.

Moreover, by providing a fourth reflection interface in addition to the first reflection interface, the second reflection interface, and the third reflection interface, it is possible to improve the viewing angle characteristics. It should be noted that the position of the fourth reflection interface that strengthens or weakens light is changed depending on the order of the lamination of the luminescent layer including two layers.

### SUMMARY

The technology disclosed in Japanese Patent Application Laid-open No. 2011-159432 is significantly useful one. However, it has been found that if materials constituting two layers that are located at distant positions with the reflection interface disposed therebetween have significantly different refractive indexes, the balance of the interference is lost, and a high frequency ripple is generated on an interference filter including the first reflection interface, the second reflection interface, and the third reflection interface, in some cases. Then, in Japanese Patent Application Laid-open No. 2011-159432, no solution to such a problem is described.

Therefore, it is desirable to provide a light emitting element that includes a first reflection interface, a second reflection interface, and a third reflection interface, and is capable of reducing the generation of high frequency ripple on an interference filter including these reflection interfaces, and to provide a display apparatus and a lighting apparatus that include such a light emitting element.

According to a first embodiment of the present disclosure, there is provided a light emitting element including a first electrode, a second electrode, and an organic layer in which a first luminescent layer and a second luminescent layer are provided from a first electrode side, the organic layer being provided between the first electrode and the second electrode, light from the organic layer being reflected on an interface of the luminescent layer and the first electrode, passing through the second electrode, and being emitted to outside, a first optical transparent layer, a second optical transparent layer, and a third optical transparent layer being provided, from a second luminescent layer side, on a side of the second luminescent layer, the side being opposite to the first luminescent layer, the light emitting element satisfying an equation (1), an equation (2), one of an equation (3-A), equation (3-B), an equation (3-C), and an equation (3-D), and one of an equation (4-A), an equation (4-B), an equation (4-C), an equation (4-D), an equation (4-E), and an equation (4-F),

$$\begin{matrix}( - {φ}_{1} / 2 π + {m}_{1} ) \cdot ( {λ}_{1} - 150 ) / 2 \leq {L}_{11} \leq ( - {φ}_{1} / 2 π + {m}_{1} ) \cdot ( {λ}_{1} + 80 ) / 2 & ( 1 ) \\ ( - {φ}_{1} / 2 π + {n}_{1} ) \cdot ( {λ}_{2} - 150 ) / 2 \leq {L}_{21} \leq ( - {φ}_{1} / 2 π + {n}_{1} ) \cdot ( {λ}_{2} + 80 ) / 2 & ( 2 ) \\ {L}_{12} \leq ( - {φ}_{2} / 2 π + {m}_{2} + 1 / 2 ) \cdot ( {λ}_{1} - 15 ) / 2 , \\ ( - {φ}_{3} / 2 π + {m}_{3} ) \cdot ( {λ}_{1} + 15 ) / 2 \leq {L}_{13} , and \\ ( - {φ}_{4} / 2 π + {m}_{4} + 1 / 2 ) \cdot ( {λ}_{1} - 150 ) / 2 \leq {L}_{14} \leq ( - {φ}_{4} / 2 π + {m}_{4} + 1 / 2 ) \cdot ( {λ}_{1} + 80 ) / 2 & ( 3 \text{-} A ) \\ {L}_{12} \leq ( - {φ}_{2} / 2 π + {m}_{2} ) \cdot ( {λ}_{1} - 15 ) / 2 , \\ ( - \text{?} / 2 π + {m}_{3} + 1 / 2 ) \cdot ( {λ}_{1} + 15 ) / 2 \leq \text{?} , and \\ ( - {φ}_{4} / 2 π + {m}_{4} + 1 / 2 ) \cdot ( {λ}_{1} - 150 ) / 2 \leq {L}_{13} \leq ( - {φ}_{4} / 2 π + {m}_{4} + 1 / 2 ) \cdot ( {λ}_{1} + 80 ) / 2 & ( 3 \text{-} B ) \\ ( - {φ}_{2} / 2 π + {m}_{2} + 1 / 2 ) \cdot ( {λ}_{1} + 15 ) / 2 \leq {L}_{12} , \\ {L}_{13} \leq ( - {φ}_{2} / 2 π + {m}_{3} ) \cdot ( {λ}_{1} - 15 ) / 2 , and \\ ( - {φ}_{4} / 2 π + {m}_{4} + 1 / 2 ) \cdot ( {λ}_{1} - 150 ) / 2 \leq {L}_{14} \leq ( - {φ}_{4} / 2 π + {m}_{4} + 1 / 2 ) \cdot ( {λ}_{1} + 80 ) / 2 & ( 3 \text{-} C ) \\ ( - \text{?} / 2 π + {m}_{2} ) \cdot ( {λ}_{1} + 15 ) / 2 \leq {L}_{12} , \\ {L}_{13} \leq ( - {φ}_{3} / 2 π + {m}_{3} + 1 / 2 ) \cdot ( {λ}_{1} - 15 ) / 2 , and \\ ( - {φ}_{4} / 2 π + {m}_{4} + 1 / 2 ) \cdot ( {λ}_{1} - 150 ) / 2 \leq \text{?} \leq ( - {φ}_{4} / 2 π + {m}_{4} + 1 / 2 ) \cdot ( {λ}_{1} + 80 ) / 2 & ( 3 \text{-} D ) \\ \text{?} \leq ( - {φ}_{2} / 2 π + \text{?} + 1 / 2 ) \cdot ( {λ}_{2} - 15 ) / 2 , and \\ ( - \text{?} / 2 π + {n}_{3} ) \cdot ( {λ}_{2} + 15 ) / 2 \leq \text{?} & ( 4 \text{-} A ) \\ \text{?} \leq ( - {φ}_{2} / 2 π + \text{?} ) \cdot ( {λ}_{2} - 15 ) / 2 , and \\ ( - \text{?} / 2 π + {n}_{3} + 1 / 2 ) \cdot ( {λ}_{2} + 15 ) / 2 \leq \text{?} & ( 4 \text{-} B ) \\ \text{?} \leq ( - {φ}_{2} / 2 π + \text{?} + 1 / 2 ) \cdot ( {λ}_{2} - 15 ) / 2 , and \\ ( - \text{?} / 2 π + {n}_{3} + 1 / 2 ) \cdot ( {λ}_{2} + 15 ) / 2 \leq \text{?} & ( 4 \text{-} C ) \\ ( - {φ}_{2} / 2 π + {n}_{2} + 1 / 2 ) \cdot ( {λ}_{2} + 15 ) / 2 \leq \text{?} , and \\ \text{?} \leq ( - {φ}_{3} / 2 π + {n}_{3} ) \cdot ( {λ}_{2} - 15 ) / 2 & ( 4 \text{-} D ) \\ ( - {φ}_{1} / 2 π + {n}_{2} ) \cdot ( {λ}_{2} + 15 ) / 2 \leq \text{?} , and \\ \text{?} \leq ( - \text{?} / 2 π + {n}_{3} + 1 / 2 ) \cdot ( {λ}_{2} - 15 ) / 2 & ( 4 \text{-} E ) \\ ( - {φ}_{2} / 2 π + {n}_{2} + 1 / 2 ) \cdot ( {λ}_{2} + 15 ) / 2 \leq \text{?} , and \\ \text{?} \leq ( - \text{?} / 2 π + {n}_{3} + 1 / 2 ) \cdot ( {λ}_{2} - 15 ) / 2 \\ \text{?} \text{indicates text missing or illegible when filed} & ( 4 \text{-} F )\end{matrix}$$

where

λ₁ represents a central wavelength in a wavelength range of light emission in the first luminescent layer (unit: nm),

λ₂ represents a central wavelength in a wavelength range of light emission in the second luminescent layer (unit: nm),

L₁₁ represents an optical distance from a first reflection interface being an interface of the first luminescent layer and the first electrode to a light emission center of the first luminescent layer (unit: nm),

L₁₂ represents an optical distance from a second reflection interface being an interface of the second luminescent layer and the first optical transparent layer to the light emission center of the first luminescent layer (unit: nm),

L₁₃ represents an optical distance from a third reflection interface being an interface of the first optical transparent layer and the second optical transparent layer to the light emission center of the first luminescent layer (unit: nm),

L₁₄ represents an optical distance from a fourth reflection interface being an interface of the second optical transparent layer and the third optical transparent layer to the light emission center of the first luminescent layer (unit: nm),

L₂₁ represents an optical distance from the first reflection interface to a light emission center of the second luminescent layer (unit: nm),

L₂₂ represents an optical distance from the second reflection interface to the light emission center of the second luminescent layer (unit: nm),

L₂₃ represents an optical distance from the third reflection interface to a light emission center of the second luminescent layer (unit: nm),

φ₁ represents a phase change of light reflected on the first reflection interface (unit: radian),

φ₂ represents a phase change of light reflected on the second reflection interface (unit: radian),

φ₃ represents a phase change of light reflected on the third reflection interface (unit: radian),

φ₄ represents a phase change of light reflected on the fourth reflection interface (unit: radian),

m₁ is an integer of not less than 0,

n₁ is an integer of not less than 0,

m₂, m₃, n₂, and n₃ are integers, and

m₄=m₃, m₃+1, or m₃−1.

It should be noted that the optical distance is also called an optical path length, and generally represents n₀₀*D₀₀, when light travels in a medium having a refractive index n₀₀ by a distance (physical distance) D₀₀.

According to a second embodiment of the present disclosure, there is provided a light emitting element including a first electrode, a second electrode, and an organic layer in which a first luminescent layer and a second luminescent layer are provided from a first electrode side, the organic layer being provided between the first electrode and the second electrode, light from the organic layer being reflected on a first reflection interface including the luminescent layer and the first electrode, passing through the second electrode, and being emitted to outside, a first optical transparent layer, a second optical transparent layer, and a third optical transparent layer being provided, from a second luminescent layer side, on a side of the second luminescent layer, the side being opposite to the first luminescent layer, the first optical transparent layer on a second luminescent layer side constituting a second reflection interface, the first optical transparent layer and the second optical transparent layer constituting a third reflection interface, the second optical transparent layer and the third optical transparent layer constituting a fourth reflection interface, the first reflection interface, the second reflection interface, the third reflection interface, and the fourth reflection interface constituting an interference filter, the first reflection interface being arranged to the following (condition-1), the second reflection interface, the third reflection interface, and the fourth reflection interface are arranged to satisfy one of a (condition-2A) and a (condition-2B), the second reflection interface and the third reflection interface being arranged to satisfy one of a (condition-3A), a (condition-3B), and a (condition-3C),

(Condition-1)

reflection of light from the first luminescent layer on the first reflection interface is enhanced and reflection of light from the second luminescent layer on the first reflection interface is enhanced,

(Condition-2A)

reflection of light from the first luminescent layer on the second reflection interface is weakened, reflection of light from the first luminescent layer on the third reflection interface is enhanced, and reflection of light from the first luminescent layer on the fourth reflection interface is weakened with one of the same order as an order of reflection of light from the first luminescent layer on the third reflection interface is enhanced, an order lower than the order of reflection, and an order higher than the order of reflection,

(Condition-2B)

reflection of light from the first luminescent layer on the second reflection interface is enhanced, reflection of light from the first luminescent layer on the third reflection interface is weakened, reflection of light from the first luminescent layer on the fourth reflection interface is weakened with one of the same order as an order of reflection of light from the first luminescent layer on the fourth reflection interface is enhanced, an order lower than the order of reflection, and an order higher than the order of reflection,

(Condition-3A)

reflection of light from the second luminescent layer on the second reflection interface is weakened, and reflection of light from the second luminescent layer on the third reflection interface is enhanced,

(Condition-3B)

reflection of light from the second luminescent layer on the second reflection interface is enhanced, and reflection of light from the second luminescent layer on the third reflection interface is weakened,

(Condition-3C)

reflection of light from the second luminescent layer on the second reflection interface is weakened, and reflection of light from the second luminescent layer on the third reflection interface is weakened.

According to one embodiment of the present disclosure, there is provided a display apparatus including the light emitting elements according to the first embodiment or the second embodiment of the present disclosure, which is arranged in a two-dimensional matrix pattern.

According to one embodiment of the present disclosure, there is provided a lighting apparatus including the light emitting element according to the first embodiment or the second embodiment of the present disclosure.

In the light emitting element according to the first embodiment of the present disclosure, the first reflection interface, the second reflection interface, the third reflection interface, and the fourth reflection interface constitute a sort of interference filter, and conditions for strengthening light are established by satisfying the equations (1) and (2) in the interference filter, as will be described later. Then, by arranging the first reflection interface, the second reflection interface, the third reflection interface, and the fourth reflection interface, it is possible to obtain an interference filter having a substantially-flat light transmittance curve in a wide wavelength range, and reduce the viewing angle dependency of luminance and chromaticity with respect to light of combined colors of two or more different colors in the visible light region significantly. Then, by defining the optical distance L₁₄ having the order m₄ that has a predetermined relationship with the order m₃ defining the optical distance L₁₃ in the equation (3-A), the equation (3-B), the equation (3-C), and the equation (3-D) for forming (generating) interference being an antiphase with respect to the high frequency ripple in the interference filter, it is possible to reduce the generation of high frequency ripple on the interference filter. On the other hand, because in the light emitting element according to the second embodiment of the present disclosure, the first reflection interface, the second reflection interface, the third reflection interface, and the fourth reflection interface are arranged so as to satisfy predetermined conditions, it is possible to reduce the generation of high frequency ripple on the interference filter. It should be noted that the effects described herein are given for exemplary purposes and are not limited. In addition, additional effects may be provided.

These and other objects, features and advantages of the present disclosure will become more apparent in light of the following detailed description of best mode embodiments thereof, as illustrated in the accompanying drawings.

Additional features and advantages are described herein, and will be apparent from the following Detailed Description and the figures.

### BRIEF DESCRIPTION OF THE FIGURES

FIG. 1A and FIG. 1B are configuration diagrams of layers constituting light emitting elements according to an example 1 and a comparative example 1, respectively;

FIG. 2 is a schematic partial cross-sectional view of a display apparatus according to the example 1;

FIG. 3A and FIG. 3B are graphs showing results obtained by calculating light transmittances of interference filters in the light emitting element according the example 1 and the light emitting element according to the comparative example 1, respectively;

FIG. 4A and FIG. 4B are graphs showing simulation results of change in luminance (Y/Y₀) obtained by, with a viewing angle being used as a parameter, changing a thickness of a second optical transparent layer in the display apparatus according the example 1 and a display apparatus according to the comparative example 1, respectively;

FIG. 5A and FIG. 5B are graphs showing simulation results of change in chromaticity (Δuv) with a viewing angle being used as a parameter, in the display apparatus according the example 1 and the display apparatus according to the comparative example 1, respectively;

FIG. 6A and FIG. 6B are graphs showing results obtained by calculating light transmittances of interference filters in light emitting elements according to an example 2 and a reference example, respectively;

FIG. 7A and FIG. 7B are graphs showing simulation results of change in luminance (Y/Y0) and change in chromaticity (Δuv) with a viewing angle being used as a parameter in the display apparatus according the example 2, respectively;

FIG. 8 is a configuration diagram of layers constituting the light emitting element according to the example 2;

FIG. 9 is a schematic partial cross-sectional view of a display apparatus according to an example 3; and

FIG. 10 is a schematic partial cross-sectional view of a lighting apparatus according to an example 4.

### DETAILED DESCRIPTION

Hereinafter, embodiments of the present disclosure will be described based on examples with reference to the drawings. However, the embodiments of the present disclosure are not limited to the above-mentioned examples and various numerical values or materials in the examples are given for exemplary purposes. It should be noted that a description will be given in the following order.

1. Light Emitting Element, Display Apparatus, and Lighting Apparatus according to First Embodiment and Second Embodiment of Present Disclosure, and General Description
2. Example 1 (Light Emitting Element and Display Apparatus according to First Embodiment and Second Embodiment of Present Disclosure)

### 3. Example 2 (Modified Example of Example 1)

### 4. Example 3 (Modified Example of Example 1 and Example 2)

5. Example 4 (Lighting Apparatus according to Embodiment of Present Disclosure), and others

(Light Emitting Element, Display Apparatus, and Lighting Apparatus According to First Embodiment and Second Embodiment of Present Disclosure, and General Description)

A light emitting element according to a first embodiment of the present disclosure, a light emitting element according to the first embodiment of the present disclosure in a display apparatus according to one embodiment of the present disclosure, a light emitting element according to the first embodiment of the present disclosure in a lighting apparatus according to one embodiment of the present disclosure (hereinafter, these light emitting elements are collectively referred to as “light emitting element or the like according to the first embodiment of the present disclosure” in some cases) may have a configuration in which an interference filter includes a first reflection interface, a second reflection interface, a third reflection interface, and a fourth reflection interface. It should be noted that the “interference filter including the first reflection interface, the second reflection interface, the third reflection interface, and the fourth reflection interface” can be restated as an “interference filter having a filtering effect based on a spectral light transmittance, which is caused by the interference due to reflection of light on the first reflection interface, the second reflection interface, the third reflection interface, and the fourth reflection interface.”

In the light emitting element or the like according to the first embodiment of the present disclosure including the above-mentioned favorable configuration, an optical thickness t₂ of a second optical transparent layer favorably satisfies the equation: 0.2*λ₁≦t₂≦0.35*λ₁. Alternatively, the optical thickness t₂ favorably satisfies the equation: 0.8×(λ₁/4)≦t₂≦1.4×(λ₁/4). It should be noted that the optical thickness t₂ can be obtained as the product of the thickness of the second optical transparent layer (physical thickness) and the refractive index of the second optical transparent layer.

A light emitting element according to a second embodiment of the present disclosure, a light emitting element according to the second embodiment of the present disclosure in a display apparatus according to one embodiment of the present disclosure, a light emitting element according to the second embodiment of the present disclosure in a lighting apparatus according to one embodiment of the present disclosure (hereinafter, these light emitting elements are collectively referred to as “light emitting element or the like according to the second embodiment of the present disclosure” in some cases) may have a configuration in which the position of the second reflection interface may be determined such that the peak position of the light transmittance of an interference filter is displaced from the peak position of light emission spectrum of light from a first luminescent layer and the peak position of light emission spectrum of light from a second luminescent layer. Moreover, in the light emitting element or the like according to the second embodiment of the present disclosure having such a configuration, the position of the third reflection interface may be determined such that the peak position of the light transmittance of the interference filter is displaced from the peak position of light emission spectrum of light from the first luminescent layer and the peak position of light emission spectrum of light from the second luminescent layer. Accordingly, it is possible to further widen the band of the interference filter. The same shall apply to the light emitting element or the like according to the first embodiment of the present disclosure.

Furthermore, in the light emitting element or the like according to the first embodiment or the second embodiment of the present disclosure having the above-mentioned favorable configuration, the decrease in luminance at the viewing angle of 45 degrees is favorably not more than 30% of that at the view angle of 0 degrees (Y₀).

Furthermore, in the light emitting element or the like according to the first embodiment or the second embodiment of the present disclosure having the above-mentioned favorable configuration, the value of displacement of chromaticity Δuv at the viewing angle of 45 degrees is favorably not more than 0.015.

Furthermore, the light emitting element or the like according to the first embodiment or the second embodiment of the present disclosure having the above-mentioned favorable configuration may have a configuration in which a metal layer having a thickness of not more than 5 nm is provided between the second luminescent layer and a first optical transparent layer. Here, examples of a material constituting the metal layer include magnesium (Mg), silver (Ag), and an alloy thereof. Light from an organic layer is transmitted through the metal layer.

Furthermore, the light emitting element or the like according to the first embodiment or the second embodiment of the present disclosure having the above-mentioned favorable configuration may have a configuration in which the second reflection interface includes a plurality of interfaces, the third reflection interfaces includes a plurality of interfaces, or the fourth interface includes a plurality of interfaces.

Furthermore, in the case where at least one of the first luminescent layer and the second luminescent layer is formed of a different color luminescent layer that emits light of two or more different colors and the light emission center of the different color luminescent layer is not regarded as being at one level, the light emitting element or the like according to the first embodiment of the present disclosure having the above-mentioned favorable configuration may further include a fourth optical transparent layer. Here, the expression of “the light emission center of the different color luminescent layer is not regarded as being at one level” represents that, for example, the light emission center of a first color of the different color luminescent layer is apart from the light emission center of a second color of the different color luminescent layer by not less than 5 nm. In such a configuration, the first reflection interface being an interface of the first luminescent layer and the first electrode, the second reflection interface including the second luminescent layer, the first optical transparent layer, the second optical transparent layer, a third optical transparent layer, and the fourth optical transparent layer, the third reflection interface, the fourth reflection interface, and the fifth reflection interface constitute an interference filter, and the change with the wavelength of the light transmittance curve of the interference filter with respect to light emitted from the different color luminescent layer to the outside of the system being used as a variable favorably shows the same tendency as the change with the wavelength of the light transmittance curve of the interference filter with respect to different light emitted from the different color luminescent layer to the outside of the system. Accordingly, it is possible to further reduce the viewing angle dependency of luminance and chromaticity with respect to light of combined colors of two or more different colors in the visible light region significantly. Moreover, in the case where at least one of the first luminescent layer and the second luminescent layer is formed of a different color luminescent layer that emits light of two or more different colors and the light emission center of the different color luminescent layer is not regarded as being at one level, the light emitting element or the like according to the second embodiment of the present disclosure having the above-mentioned favorable configuration may further include a fourth optical transparent layer. In such a configuration, the change with the wavelength of the light transmittance curve of the interference filter with respect to light emitted from the different color luminescent layer to the outside of the system being used as a variable favorably shows the same tendency as the change with the wavelength of the light transmittance curve of the interference filter with respect to different light emitted from the different color luminescent layer to the outside of the system.

Furthermore, the light emitting element or the like according to the first embodiment or the second embodiment of the present disclosure having the above-mentioned favorable configuration may have a configuration in which a first electrode, an organic layer, and a second electrode are laminated on a substrate (referred to as “first substrate” in some cases for the sake of convenience) in the stated order. It should be noted that such a configuration is referred to as “upper surface light emission type” for the sake of convenience. In this case, a transparent conductive material layer having a thickness of not less than 0.5 μm, a transparent insulating layer having a thickness of not less than 0.5 μm, a resin layer having a thickness of not less than 0.5 μm, a glass layer having a thickness of not less than 0.5 μm, or an air layer having a thickness of not less than 0.5 μm may be further formed on a surface of the third optical transparent layer, which is opposite to the second optical transparent layer. It should be noted that the outermost layer on the upper side of the second electrode is formed of a second substrate.

Alternatively, in the light emitting element or the like according to the first embodiment or the second embodiment of the present disclosure having the above-mentioned favorable configuration, the second electrode, an organic layer, and the first electrode may be laminated on the first substrate in the stated order. It should be noted that such a configuration is referred to as “lower surface light emission type” for the sake of convenience. In this case, a transparent conductive material layer having a thickness of not less than 1 μm, a transparent insulating layer having a thickness of not less than 1 μm, a resin layer having a thickness of not less than 1 μm, a glass layer having a thickness of not less than 1 μm, or an air layer having a thickness of not less than 1 μm may be formed on a surface of the third optical transparent layer, which is opposite to the second optical transparent layer. It should be noted that normally, the outermost layer on the upper side of the first electrode is formed of the second substrate.

In general, a part of incident light is transmitted through a reflection interface including a layer A and a layer B formed of a transparent material, and the remaining light is reflected on the reflection interface. Therefore, a phase change (phase shift) is caused in reflection light. A phase change φ_{AB} of light when being reflected on the reflection interface including the layer A and the layer B can be obtained by measuring complex refractive indexes (n_{A}, k_{A}) of the layer A and complex refractive indexes (n_{B}, k_{B}) of the layer B, and making a calculation based on these values (see, for example, Principles of Optics, Max Born and Emil Wolf, 1974 (PERGAMON PRESS) or the like). It should be noted that the refractive index of the organic layer and each optical transparent layer can be measured using a spectral ellipsometry measurement apparatus.

The upper surface light emission type display apparatus may have a configuration in which the organic layer emits white light and the second substrate includes a color filter. In addition, the second substrate may include a light-shielding film (black matrix). Similarly, the lower surface light emission type display apparatus may have a configuration in which the organic layer emits white light and the first substrate includes a color filter or a light-shielding film (black matrix).

In the display apparatus according an embodiment of the present disclosure having a configuration in which one pixel (or sub-pixel) includes one light emitting element, pixels (or sub-pixels) are arranged in, but not limited to, a stripe pattern, a diagonal pattern, a delta pattern, or a rectangle pattern. Moreover, in the configuration in which one pixel (or sub-pixel) includes a plurality of light emitting elements, pixels may be arranged in, but not limited to, a stripe pattern.

In the case where the first electrode is caused to function as an anode electrode, examples of a material (light reflecting material) forming the first electrode include metal having a high value of work function such as platinum (Pt), gold (Au), silver (Ag), chromium (Cr), tungsten (W), nickel (Ni), copper (Cu), iron (Fe), cobalt (Co), and tantalum (Ta) and an alloy (e.g., an Ag—Pd—Cu alloy including silver as a main component and 0.3% by mass to 1% by mass of palladium (Pd) and 0.3% by mass to 1% by mass of copper (Cu), and an Al—Nd alloy). Furthermore, in the case where a conductive material having a low value of work function such as aluminum (Al) and an alloy including aluminum and a high light reflectance is used, the first electrode can be used as an anode electrode by providing an appropriate hole injection layer to improve the hole injection property, for example. The thickness of the first electrode is, for example, 0.1 μm to 1 μm. Alternatively, a transparent conductive material having high hole injection properties such as indium and tin oxide (ITO) or indium and zinc oxide (IZO) may be laminated on a reflection film having a high light reflectivity such as a dielectric multilayer and aluminum (Al). On the other hand, in order to cause the first electrode to function as a cathode electrode, it is favorable to form the first electrode of a conductive material having a low value of work function and a high light reflectance. By providing an appropriate electron injection layer on a conductive material having a high light reflectance used for an anode electrode to improve the electron injection properties, the first electrode can be used also as a cathode electrode.

On the other hand, in order to cause the second electrode to function as a cathode electrode, a conductive material that has a low value of work function so that electrons can be efficiently injected into the organic layer, through which emitted light is transmitted, is favorably used as a material forming the second electrode (a semi-light transmitting material or a light transmitting material). Examples of such a material include metal or an alloy having a low value of work function, such as aluminum (Al), silver (Ag), magnesium (Mg), calcium (Ca), sodium (Na), strontium (Sr), alkali metal or alkaline earth metal and silver (Ag) (e.g., alloy of magnesium (Mg) and silver (Ag) (Mg—Ag alloy)), an alloy of magnesium-calcium (Mg—Ca alloy), and an alloy of aluminum (Al) and lithium (Li) (Al—Li alloy). Of these, the Mg—Ag alloy is favorable, and the volume ratio of magnesium and silver is, for example, 2:1 to 30:1. Alternatively, the volume ratio of magnesium and silver may be 2:1 to 10:1. The thickness of the second electrode is, for example, 4 nm to 50 nm, favorably, 4 nm to 20 nm, and more favorably, 6 nm to 12 nm. Alternatively, the second electrode may have a laminated structure in which the above-mentioned material layer and a so-called transparent electrode (having a thickness of 3×10⁻⁸ m to 1×10⁻⁶ m, for example) including ITO or IZO are laminated from the organic layer side. In the case of the laminated structure, the thickness of the above-mentioned material layer can be reduced to 1 nm to 4 nm. Alternatively, the second electrode may be formed of only the transparent electrode. On the other hand, in order to cause the second electrode to function as an anode electrode, the second electrode favorably includes a conductive material having a high value of work function, through which emitted light is transmitted.

The first optical transparent layer, the second optical transparent layer, or the third optical transparent layer may be formed of the second electrode having such a configuration, and the second electrode may be provided separately from the first optical transparent layer, the second optical transparent layer, and the third optical transparent layer. Alternatively, by providing a bus electrode (auxiliary electrode) including a low resistance material such as aluminum, an aluminum alloy, silver, a silver alloy, copper, a copper alloy, gold, and gold alloy for the second electrode, the resistance may be reduced as the whole second electrode.

Examples of a method of forming the first electrode or the second electrode include evaporation methods such as an electron beam evaporation method, a hot filament evaporation method, and a vacuum evaporation method, combinations of a sputtering method, a chemical vapor deposition method (CVD method), MOCVD method, or an ion plating method with an etching method, various printing methods such as a screen printing method, an inkjet printing method, and a metal mask printing method, a plating method (electroplating method or non-electrolytic plating method), a lift-off method, a laser ablation method, and a sol-gel method. According to the various printing methods or plating methods, it is possible to directly form the first electrode or the second electrode having a desired shape (pattern). It should be noted that in the case where the first electrode or the second electrode is formed after the organic layer is formed, it is favorable to form the first electrode or the second electrode particularly based on a deposition method having small energy of deposition particles such as a vacuum deposition method or a deposition method such as an MOCVD method from a viewpoint of preventing the organic layer from being damaged, for example. If the organic layer is damaged, a non-light emitting pixel (or non-light emitting sub-pixel) called “dead pixel” may be generated due to leak current. Moreover, it is favorable to perform the steps from forming of the organic layer to the forming of these electrodes without exposing to the atmosphere from a viewpoint of preventing the organic layer from being degraded due to water in the atmosphere. In some cases, one of the first electrode and the second electrode does not need to be patterned.

In the display apparatus or the lighting apparatus according to one embodiment of the present disclosure (hereinafter, collectively referred to as “display apparatus or the like according to one embodiment of the present disclosure” in some cases), a plurality of light emitting elements are formed on the first substrate. Here, examples of the first substrate or the second substrate include an organic polymer (having a configuration of a polymeric material such as a plastic film, a plastic sheet, or a plastic substrate including polymeric material and having flexibility) such as a high strain point glass substrate, a soda-glass (Na₂O—CaO—SiO₂) substrate, a borosilicate glass (Na₂O—B₂O₃—SiO₂) substrate, a forsterite (2MgO—SiO₂) substrate, a lead glass (Na₂O—PbO—SiO₂) substrate, non-alkali glass, various glass substrates on which an insulating film is formed, a quartz substrate, a quartz substrate on which an insulating film is formed, a silicon substrate on which an insulating film is formed, polymethyl methacrylate (polymethylmethacrylate, PMMA), polyvinyl alcohol (PVA), polyvinyl phenol (PVP), polyethersulfone (PES), polyimide, polycarbonate, and polyethylene terephthalate (PET). The material forming the first substrate may be the same as or different from that forming the second substrate. It should be noted that in the upper surface light emission type display apparatus, the second substrate needs to be transparent with respect to light emitted from the light emitting element and the lower surface light emission type display apparatus needs to be transparent with respect to light emitted from the light emitting element.

Examples of the display apparatus or the like according to one embodiment of the present disclosure include an organic electroluminescence display apparatus (abbreviated as organic EL display apparatus), and if the organic EL display apparatus is a color organic EL display apparatus, the organic EL elements constituting the organic EL display apparatus constitute sub-pixels, as described above. Here, one pixel includes, for example, three types of sub-pixels of a red light emission sub-pixel that emits red light, a green light emission sub-pixel that emits green light, and a blue light emission sub-pixel that emits blue light, as described above. Therefore, in this case, if the number of organic EL elements constituting the organic EL display apparatus is N×M, the number of pixels is (N×M)/3. The organic EL display apparatus can be used as a monitor apparatus constituting a personal computer, or a monitor apparatus incorporated into a television receiver, a mobile phone, a PDA (Personal Digital Assistant), or a game apparatus, for example. Alternatively, the organic EL display apparatus can be applied to an electronic view finder (EVF) or a head mounted display (HMD). Moreover, the lighting apparatus according to one embodiment of the present disclosure can be used as a lighting apparatus such as a back light apparatus for a liquid crystal display apparatus and a planar light source apparatus.

The organic layer includes a luminescent layer (e.g., luminescent layer including an organic luminescent material). Specifically, the organic layer may have a laminated structure of a hole transport layer, a luminescent layer, and an electron transport layer, a laminated structure of a hole transport layer and a luminescent layer serving also as an electron transport layer, or a laminated structure of a hole injection layer, a hole transport layer, a luminescent layer, an electron transport layer, and an electron injection layer, for example. These laminated structures are called “tandem unit.” Specifically, the organic layer may have a two-stage tandem structure in which a first tandem unit, a connection layer, and a second tandem unit are laminated. Furthermore, the organic layer may have a three-stage (or more) tandem structure in which three or more tandem units are laminated. In these cases, by changing the light emission colors for the respective tandem units to red, green, and blue, it is possible to obtain an organic layer that emits white light as a whole. Examples of the method of forming the organic layer include a physical vapor deposition method (PVD method) such as a vacuum deposition method, a printing method such as a screen printing method and an inkjet printing method, a laser transfer method in which a laser is applied to a laminated structure of a laser absorbing layer formed on a transfer substrate and an organic layer to separate the organic layer from the laser absorbing layer and transfer the organic layer, and various applying methods. In the case where the organic layer is formed based on a vacuum deposition method, it is possible to obtain the organic layer by using a so-called metal mask and depositing a material that has passed through an opening provided in the metal mask, for example. It is also possible to form the organic layer on the entire surface without patterning the organic layer.

In the upper surface light emission type display apparatus or the like, the first electrode is provided on an interlayer insulating layer, for example. Then, the interlayer insulating layer covers a light emitting element driving unit formed on the first substrate. The light emitting element driving unit includes one or a plurality of thin-film transistors (TFT), and the TFT and the first electrode are electrically connected to each other via a contact plug provided on the interlayer insulating layer. As a material forming the interlayer insulating layer, an SiO₂ material such as SiO₂, BPSG, PSG, BSG, AsSG, PbSG, SiON, SOG (spin-on glass), low melting point glass, and glass paste, SiN material, polyimide resin, novolak resin, acrylic resin, or insulating resin such as polybenzoxazole can be used alone or can be appropriately combined to be used. In order to form the interlayer insulating layer, well-known processes such as a CVD method, an applying method, a sputtering method, and various printing methods can be used. The lower surface light emission type display apparatus or the like having a configuration and structure in which light from the light emitting element passes through the interlayer insulating layer, the interlayer insulating layer needs to include a transparent material with respect to the light from the light emitting element, and the light emitting element driving unit needs to be formed so as not to block the light from the light emitting element. In the lower surface light emission type display apparatus or the like, it is possible to provide a light emitting element driving unit on the upper side of the first electrode.

On the upper side of the organic layer, it is favorable to provide an insulating or conductive protection film to prevent water from reaching the organic layer. The protection film is favorably formed based on a deposition method having small energy of deposition particles such as a vacuum deposition method, or deposition methods such as a CVD method and a MOCVD method, particularly. This is because the influence on the underlying layer can be reduced. Alternatively, in order to prevent the luminance from being reduced due to the degradation of the organic layer, it is favorable to set the deposition temperature to the ambient temperature. Furthermore, in order to prevent the protection film from being removed, it is favorable to deposit the protection film under the conditions in which the stress on the protection film is minimized. Moreover, the protection film is favorably formed without exposing the formed electrode to the atmosphere. Accordingly, it is possible to prevent the organic layer from being degraded due to water or oxygen in the atmosphere. Furthermore, in the case where the display apparatus or the like is an upper surface light emission type one, the protection film favorably includes a material through which 80% or more of light generated in the organic layer is transmitted, for example. Specific examples of such a material include an inorganic amorphous insulating material such as the following materials. Because such an inorganic amorphous insulating material does not generate a grain, it has low permeability and therefore forms a favorable protection film. Specifically, as a material forming the protection film, a material that is transparent with respect to light emitted from the luminescent layer and is dense, through which water does not pass, is favorably used. More specifically, for example, amorphous silicon (α-Si), amorphous carbonized silicon (α-SiC), amorphous silicon nitride (α-Si₁₋ₓNₓ), amorphous silicon oxide (α-Si_{1-y}O_{y}), amorphous carbon (α-C), amorphous silicon oxide nitride (α-SiON), or Al₂O₃ is used. It should be noted that in order to form the protection film of a conductive material, the protection film may include a transparent conductive material such as ITO and IZO. The protection film may constitute at least one of the first optical transparent layer, the second optical transparent layer, and the third optical transparent layer.

Examples of a material forming the first optical transparent layer, the second optical transparent layer, or the third optical transparent layer include, in addition to the above-mentioned various materials, metal oxide such as molybdenum oxide, niobium oxide, zinc oxide, and tin oxide, and various organic materials.

### Example 1

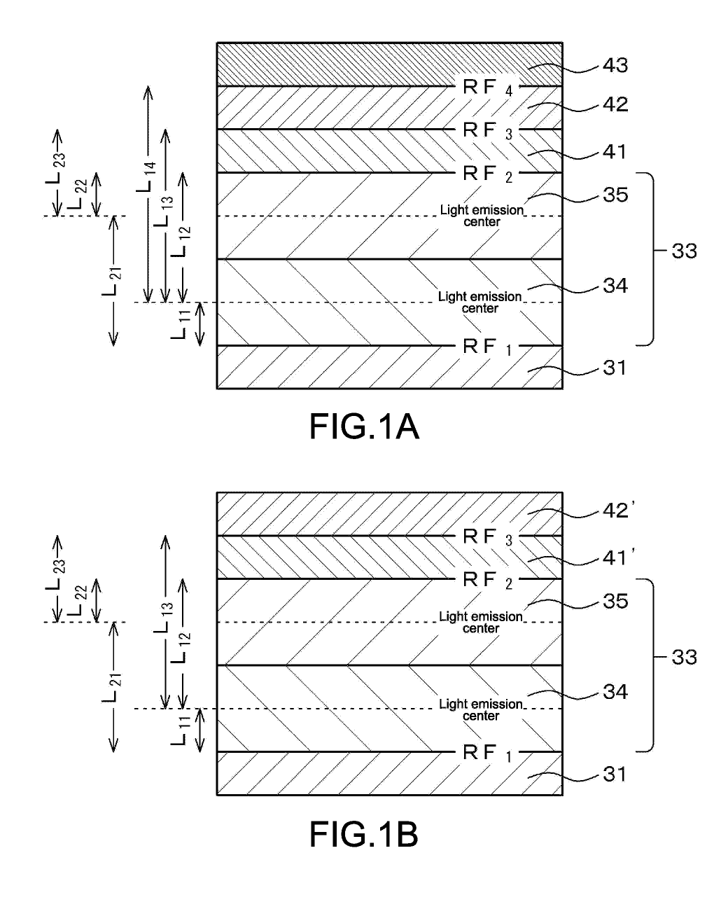

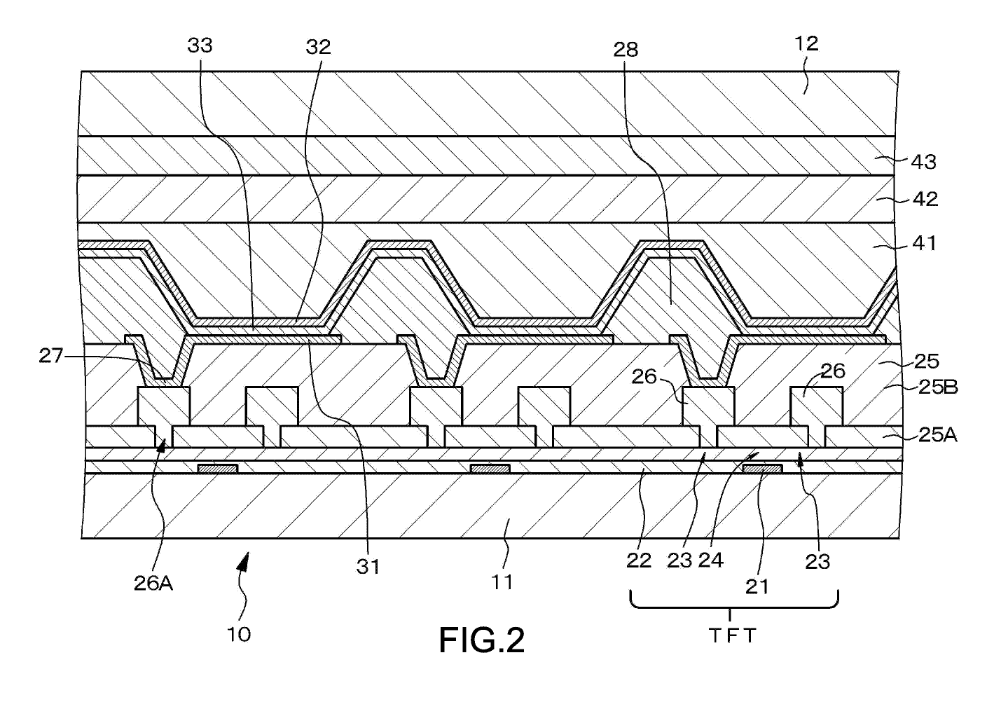

An embodiment 1 relates to light emitting elements according to the first embodiment and the second embodiment of the present disclosure, and a display apparatus according to one embodiment of the present disclosure. FIG. 1A is a configuration diagram of layers constituting a light emitting element according to the example 1, and FIG. 2 is a schematic partial cross-sectional view of a display apparatus according the example 1.

A light emitting element 10 according to the example 1, specifically, organic EL element 10, includes a first electrode 31, a second electrode 32, and an organic layer 33 that is provided between the first electrode 31 and the second electrode 32 and is formed by laminating a first luminescent layer 34 and a second luminescent layer 35 from a first electrode side. Light from the organic layer 33 is reflected on the interface of the first luminescent layer 34 and the first electrode 31 (first reflection interface RF₁), passes through the second electrode 32, and is emitted to the outside. On a side of the second luminescent layer 35, which is opposite to the first luminescent layer 34, a first optical transparent layer 41, a second optical transparent layer 42, and a third optical transparent layer 43 are provided from a second luminescent layer side.

Alternatively, the light emitting element 10 according to the example 1, specifically, the organic EL element 10, includes the first electrode 31, the second electrode 32, and the organic layer 33 that is provided between the first electrode 31 and the second electrode 32 and is formed by laminating the first luminescent layer 34 and the second luminescent layer 35 from the first electrode side. Light from the organic layer 33 is reflected on the first reflection interface RF₁ including the first luminescent layer 34 and the first electrode 31, passes through the second electrode 32, and is emitted to the outside. On the side of the second luminescent layer 35, which is opposite to the first luminescent layer 34, the first optical transparent layer 41, the second optical transparent layer 42, and the third optical transparent layer 43 are provided from the second luminescent layer side. The interface of the first optical transparent layer 41 on the second luminescent layer side constitutes a second reflection interface RF₂, the first optical transparent layer 41 and the second optical transparent layer 42 constitute a third reflection interface RF₃, the second optical transparent layer 42 and the third optical transparent layer 43 constitute a fourth reflection interface RF₄, the first reflection interface RF₁, the second reflection interface RF₂, the third reflection interface RF₃, and the fourth reflection interface RF₄ constitute an interference filter, the first reflection interface RF₁ is arranged so as to satisfy the above-mentioned (condition-1), the second reflection interface RF₂, the third reflection interface RF₃, and the fourth reflection interface RF₄ are arranged so as to satisfy one of the above-mentioned (condition-2A) and (condition-2B), and the second reflection interface RF₂ and the third reflection interface RF₃ are arranged so as to satisfy one of the above-mentioned (condition-3A), (condition-3B), and (condition-3C).

Moreover, an organic EL display apparatus according to the example 1 or examples 2 and 3 to be described later includes such light emitting elements arranged in a two-dimensional matrix pattern. Then, on a first substrate 11, the first electrode 31, the organic layer 33, and the second electrode 32 are laminated in the stated order. Specifically, the organic EL display apparatus includes:

(A) the first substrate 11 on which a plurality of light emitting elements 10 in which the first electrode 31, the organic layer 33 including the first luminescent layer 34 and the second luminescent layer 35 formed of an organic luminescent material, and the second electrode 32 are laminated are formed; and

(B) a second substrate 12 arranged on the upper side of the second electrode 32. Light emitted from the luminescent layer is emitted to the outside via the second substrate 12. Specifically, the display apparatus according to the example 1 is an upper surface light emission type display apparatus. Between the organic layer 33 and the second electrode 32, a metal layer (not shown) that is formed of magnesium (Mg), silver (Ag), an alloy thereof, or the like, and has a thickness of not more than 5 nm is provided. However, the display apparatus is not limited to such a configuration.

It should be noted that although not shown, a transparent conductive material layer having a thickness of not less than 0.5 μm, a transparent insulating layer having a thickness of not less than 0.5 μm, a resin layer having thickness of not less than 0.5 μm, a glass layer having a thickness of not less than 0.5 μm, or an air layer having a thickness of not less than 0.5 μm may be further formed on a surface of the third optical transparent layer 43, which is opposite to the second optical transparent layer 42, i.e., between the third optical transparent layer 43 and the second substrate 12.

The organic EL display apparatus according to the example 1 or the example 2 and the example 3 to be described later is a high definition display apparatus applied to an electronic view finder (EVF) or a head mounted display (HMD). Alternatively, the organic EL display apparatus is a large organic EL display apparatus such as a television receiver.

Then, one pixel includes three types of sub-pixels of a red light emission sub-pixel that emits red light, a green light emission sub-pixel that emits green light, and a blue light emission sub-pixel that emits blue light. The second substrate 12 includes a color filter (not shown). The light emitting element 10 emits white light, and the respective sub-pixels include a combination of the light emitting element 10 that emits white light and a color filter. The color filter includes an area that makes transmitted light red, an area that makes transmitted light green, and an area that makes transmitted light blue. Moreover, a light-shielding film (black matrix) may be provided between color filters. The number of pixels is, for example, 1920×1080, and one light emitting element 10 includes one sub-pixel. The number of light emitting elements (specifically, organic EL elements) 10 is three times as large as the number of pixels. It should be noted that in the case where no color filter is provided, the organic EL display apparatus is a so-called black-and-white display apparatus.

Here, in the example 1, m₁=0 and n₁=1. Moreover, refractive indexes n₀₀, n₀₁, n₀₂, and n₀₃ of the organic layer 33, the first optical transparent layer 41, the second optical transparent layer 42, and the third optical transparent layer 43, and various parameters are described in the following Table 1. The first luminescent layer 34 has, specifically, two-layered structure of a green luminescent layer that generates green light and a red luminescent layer that generates red light, i.e., includes a different color luminescent layer. However, the light emission center of the different color luminescent layer can be regarded as being at one level, and mean values of the light emission wavelength are described in the following Table 1. The first luminescent layer 34 may be used as a luminescent layer having a single-layered structure that emits yellow light.

Moreover, although the details will be described later, the first reflection interface RF₁, the second reflection interface RF₂, the third reflection interface RF₃, and the fourth reflection interface RF₄ constitute the interference filter. It should be noted that even if m₄=m₃−1, the third reflection interface is located between the first optical transparent layer and the second optical transparent layer, and the fourth reflection interface is located between the second optical transparent layer and the third optical transparent layer.

In the example 1 or the example 2 and the example 3 to be described later, the first electrode 31 is used as an anode electrode, and the second electrode 32 is used as a cathode electrode. The first electrode 31 includes a light reflecting material, specifically, an Al—Nd alloy, and the second electrode 32 includes a transparent conductive material. The first electrode 31 is formed based on a combination of a vacuum deposition method and an etching method. Moreover, the second electrode 32 is deposited by a deposition method having small energy of deposition particles such as a vacuum deposition method, particularly, and is not patterned.

Here, in the example 1 or the example 2 and the example 3 to be described later, the first electrode 31 constituting the light emitting element (organic EL element) 10 is provided on an interlayer insulating layer 25 (more specifically, upper layer interlayer insulating layer 25B) including SiON formed based on a CVD method. Then, the interlayer insulating layer 25 (more specifically, lower layer interlayer insulating layer 25A) covers an organic EL element driving unit formed on the first substrate 11. The organic EL element driving unit includes a plurality of TFTs, and the respective TFT and the first electrode 31 are electrically connected to each other via a contact plug 27, a wiring 26, and a contact plug 26A provided on the interlayer insulating layer (more specifically, the upper layer interlayer insulating layer 25B). A portion of the organic layer 33, which emits light actually, is surrounded by an insulating layer 28. It should be noted that in the figure, one TFT is shown for one organic EL element driving unit. The TFT includes a gate electrode 21 formed on the first substrate 11, a gate insulating film 22 formed on the first substrate 11 and the gate electrode 21, source-drain areas 23 that are provided on a semiconductor layer formed on the gate insulating film 22, and a channel forming area 24 that corresponds to a portion of the semiconductor layer, which is located on the upper side of the gate electrode 21 between the source-drain areas 23. It should be noted that in the shown example, the TFT is a bottom-gate type TFT, but may be a top-gate type TFT. The gate electrode 21 of the TFT is connected to a scanning circuit (not shown).

In the example 1 or the example 2 and the example 3 to be described later, the first substrate 11 includes a silicon substrate, non-alkali glass, or quartz glass, and the second substrate 12 includes non-alkali glass or quarts glass.

The organic layer 33, more specifically, has the following configuration and structure. However, such a configuration and structure is given for exemplary purposes, and can be modified appropriately. It should be noted that the thickness of the hole injection layer is, for example, 1 nm to 20 nm, the thickness of the hole transport layer is, for example, 15 nm to 100 nm, the thickness of the luminescent layer is, for example, 5 nm to 50 nm, and the thickness of the electron transport layer is, for example, 15 nm to 200 nm.

On the first electrode 31, a buffer layer constituting the organic layer 33 is formed. The buffer layer is a layer for preventing leaking, and includes, for example, hexaazatriphenylene (HAT). On the buffer layer, a hole transport layer including α-NPD[N,N′-di(1-naphthyl)-N,N′-diphenyl-[1,1′-biphenyl]-4,4′-diamine] is formed, for example. On the hole transport layer, a green luminescent layer and a red luminescent layer are continuously formed. The green luminescent layer may include Alq3[tris(8-quinolinolato)aluminum(III)], and the red luminescent layer can be obtained by doping pyrromethene boron complex to rubrene serving as a host material. Furthermore, an electron transport layer including BCP (2,9-dimethyl-4,7-diphenyl-1,10-phenanthroline), and an electron injection layer including lithium fluoride (LiF) are formed thereon. The first luminescent layer 34 is formed to have such a laminated structure.

On the first luminescent layer 34, a connection layer including Alq3 doped with Mg by 5% or hexaazatriphenylene (HAT) is formed.

On the connection layer, a hole injection layer serving also as a hole transport layer including α-NPD is formed. A blue luminescent layer (having a thickness of 20 nm) is formed thereon. The blue luminescent layer can be obtained by doping a diamino chrysene derivative to ADN serving as a host material. Furthermore, an electron transport layer including BCP or the like, and an electron injection layer including lithium fluoride (LiF) are formed thereon. The second luminescent layer 35 is formed to have such a laminated structure.

Because the above-mentioned light emitting element can be produced using a well-known method, the detailed description of the production method will be omitted.

The light emitting element 10 according to the example 1 satisfies the above-mentioned equation (1) and equation (2), any one of the equation (3-A), the equation (3-B), the equation (3-C), and the equation (3-D), and any one of the equation (4-A), the equation (4-B), the equation (4-C), the equation (4-D), the equation (4-E), and the equation (4-F).

It should be noted that if these equations are expressed in another way, as follows.

Specifically,

if λ₁−150≦λ₁₁≦λ₁+80,

λ₂−150≦λ₂₁≦λ₂+80,

λ₂₂≦λ₂−15 or λ₂₃≧λ₂+15, or

λ₂₃≦λ₂−15 or λ₂₂≧λ₂+15, and

λ₁−150≦λ₁₄≦λ₁+80,

the equation (A), the equation (B),

one of the equation (C-1) and the equation (C-2),

and

one of the equation (D-1), the equation (D-2), and the equation (D-3) are satisfied.

2*L₁₁/λ₁₁+φ₁/2π=m₁ (A)

2*L₂₁/λ₂₁+φ₁/2π=n₁ (B)

2*L₁₂/λ₁₂+φ₂/2π=m₂+½,

2*L₁₃/λ₁₃+φ₃/2π=m₃, and

2*L₁₄/λ₁₄+φ₄/2π=m₄+½ (C-1)

2*L₁₂/λ₁₂+φ₂/2π=m₂,

2*L₁₃/λ₁₃+φ₃/2π=m₃+½, and

2*L₁₄/λ₁₄+φ₄/2π=m₄+½ (C-2)

2*L₂₂/λ₂₂+φ₂/2π=n₂+½ and

2*L₂₃/λ₂₃+φ₂₃/2π=n₃ (D-1)

2*L₂₂/λ₂₂+φ₂/2π=n₂ and

2*L₂₃/λ₂₃+φ₃/2π=n₃+½ (D-2)

2*L₂₂/λ₂₂+φ₂/2π=n₂+½ and

2*L₂₃/λ₂₃+φ₃/2π=n₃+½ (D-3)

Here, from the above-mentioned equation, λ₂₂≦₂−15 or λ₂₃≧λ₂+15, if “λ₂₂≦λ₂−15” is adopted, by defining the optical distance L₂₂ from the second reflection interface to the light emission center of the second luminescent layer, it is possible to planarize the light transmittance curve of the interference filter. If “λ₂₃≧λ₂+15” is adopted, by defining the optical distance L₂₃ from the third reflection interface to the light emission center of the second luminescent layer, it is possible to planarize the light transmittance curve of the interference filter. It should be noted that whether “λ₂₂≦₂−15” or “λ₂₃≧λ₂+15” is adopted is a design item. Similarly, from the equation “λ₂₃≦λ₂−15 or λ₂₂≧λ₂+15”, if “λ₂₃≦λ₂−15” is adopted, by defining the optical distance L₂₃ from the third reflection interface to the light emission center of the second luminescent layer, it is possible to planarize the light transmittance curve of the interference filter. If “λ₂₂≧λ₂+15” is adopted, by defining the optical distance L₂₂ from the second reflection interface to the light emission center of the second luminescent layer, it is possible to planarize the light transmittance curve of the interference filter. It should be noted that whether “λ₂₃≦λ₂−15” or “λ₂₂≧λ₂+15” is adopted is also a design item. Furthermore, whether “λ₂₂≦λ₂−15 or λ₂₃≧λ₂+15” or “λ₂₃≦λ₂−15 or λ₂₂≧λ₂+15” is adopted is also a design item. Here, the optical distance L represents a value obtained by taking into account of the wavelength dependency of the refractive index of a medium through which light passes.

### [Table 1]

n₀₀: 1.75
n₀₁: 2.00
n₀₂: 1.80
n₀₃: 1.50×
λ₁: 575 nm
λ₂: 460 nm

### L₁₁: 96 nm

### L₁₂: 1002 nm

### L₁₃: 1282 nm

### L₁₄: 1453 nm

### L₂₁: 319 nm

### L₂₂: 792 nm

### L₂₃: 1072 nm

It should be noted that the difference between the refractive index n₀₀ of the organic layer 33 and the refractive index n₀₁ of the first optical transparent layer 41 is not less than 0.15, the difference between the refractive index n₀₁ of the first optical transparent layer 41 and the refractive index n₀₂ of the second optical transparent layer 42 is not less than 0.15, and the difference between the refractive index n₀₂ of the second optical transparent layer 42 and the refractive index n₀₃ of the third optical transparent layer 43 is not less than 0.15. Moreover, the optical thickness t2 of the second optical transparent layer satisfies the equation, t₂≈(¼)λ₁, and satisfies the equation, 0.2*λ₁≦t₂≦0.35*λ₁, or 0.8×(λ₁/4)≦t₂≦1.4×(λ₁/4).

As a result,

2*L₁₁/λ₁₁+φ₁/2π=0

2*L₂₁/λ₂₁+φ₁/2π=−1 where

λ₁−150=425 nm≦λ₁₁=560 nm≦λ₁+80=655 nm

λ₂−150=310 nm≦λ₂₁=460 nm≦λ₂+80=540 nm,

the equation (A) and the equation (B),

in other words, the equation (1) and the equation (2) are satisfied. It should be noted that values including λ₁₁₌₅₆₀ nm and λ₂₁=460 nm are determined based on the design aspect of the display apparatus. Moreover,

2*L₁₂/λ₁₂+φ₂/2π=3+½

2*L₁₃/λ₁₃+φ₃/2π=5

2*L₁₄/λ₁₄+φ₄/2π=5+½

2*L₂₂/λ₂₂+φ₂/2π=4

2*L₂₃/λ₂₃+φ₃/2π=4+½

where λ₂₂=396 nm≦λ₂−15=445 nm, which satisfies the first step, the second step, and the third step of the equation (C-1), and the equation (D-2). Here, if m=−0, values of λ₁₂, λ₁₃, and λ₁₄ are not limited, and the first step, the second step, and the third step of the equation (C-1) are satisfied by applying an appropriate value. It should be noted that if m≧1, the values are limited to satisfy the equation,

λ₁₂≦λ₁−15 or λ₁₃≧λ₁+15, or

λ₁₃≦λ₁−15 or λ₁₂≧λ₁+15.

In this case, a similar equation to the above-mentioned equation “λ₂₂≦λ₂−15 or λ₂₃≧λ₂+15 or λ₂₃≦λ₂−15 or λ₂₂≧λ₂+15” is applied to λ₁₂, λ₁₃, L₁₂, and L₁₃.

For comparison, as shown in FIG. 1B being a configuration diagram of the layers, a light emitting element (light emitting element according to a comparative example 1) in which only two layers of a first optical transparent layer 41′ and a second optical transparent layer 42′ are provided, from the second luminescent layer side, on the side of the second luminescent layer 35, which is opposite to the first luminescent layer 34 is assumed. The light emitting element according to the comparative example 1 satisfies the equations (1) to (6) disclosed in Japanese Patent Application Laid-open No. 2011-159432 and at least one of the equations (7) and (8). Various parameters such as the refractive indexes n₀₀, n₀₁, and n₀₂ of the organic layer 33, the first optical transparent layer 41′, and the second optical transparent layer 42′ are shown in the above-mentioned Table 1 excluding the value of L₁₄, specifically.

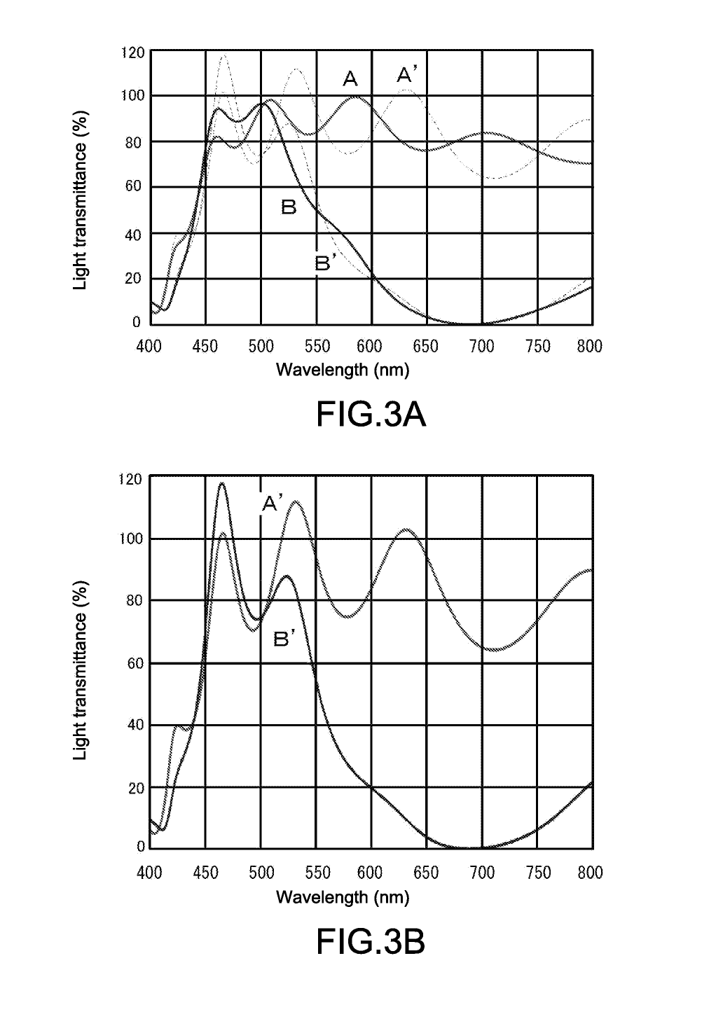

The results obtained by calculating light transmittances of light (wavelength λ₁) emitted from the first luminescent layer 34 and light (wavelength λ₂) emitted from the second luminescent layer 35 in a sort of interference filter including the first reflection interface RF₁, the second reflection interface RF₂, the third reflection interface RF₃, and the fourth reflection interface RF₄ of the light emitting element according to the example 1 are shown in FIG. 3A. Similarly, the results obtained by calculating light transmittances of light (wavelength λ₁) emitted from the first luminescent layer 34 and light (wavelength λ₂) emitted from the second luminescent layer 35 in a sort of interference filter including the first reflection interface RF₁, the second reflection interface RF₂, and the third reflection interface RF₃ of the light emitting element according to the comparative example 1 are shown in FIG. 3A and FIG. 3B. It should be noted that in FIG. 3A, data related to light from the first luminescent layer 34 of the light emitting element according the example 1 is represented by a solid line “A,” and data related to light from the second luminescent layer 35 of the light emitting element according the example 1 is represented by a solid line “B.” Moreover, in FIG. 3A and FIG. 3B, data related to light from a first luminescent layer 34′ of the light emitting element according the comparative example 1 is represented by a dotted line “A′” and a solid line “A′,” (these data are the same data) and data related to light from a second luminescent layer 35′ of the light emitting element according the comparative example 1 is represented by a dotted line “B′” and a solid line “B,” (these data are the same data), respectively.

It can be seen that from FIG. 3A and FIG. 3B, in the light emitting element according the example 1 as compared to the light emitting element according to the comparative example 1, generation of a high frequency ripple on a sort of interference filter including the first reflection interface RF₁, the second reflection interface RF₂, the third reflection interface RF₃, and the fourth reflection interface RF₄, is reduced. Moreover, because the position of the second reflection interface RF₂ is determined such that the peak position of the light transmittance of the interference filter is displaced from the peak position of light emission spectrum of light from the first luminescent layer 34 and the peak position of light emission spectrum of light from the second luminescent layer 35, and the position of the third reflection interface RF₃ is determined such that the peak position of the light transmittance of the interference filter is displaced from the peak position of light emission spectrum of light from the first luminescent layer 34 and the peak position of light emission spectrum of light from the second luminescent layer 35, it is possible to further widen the band of the interference filter.

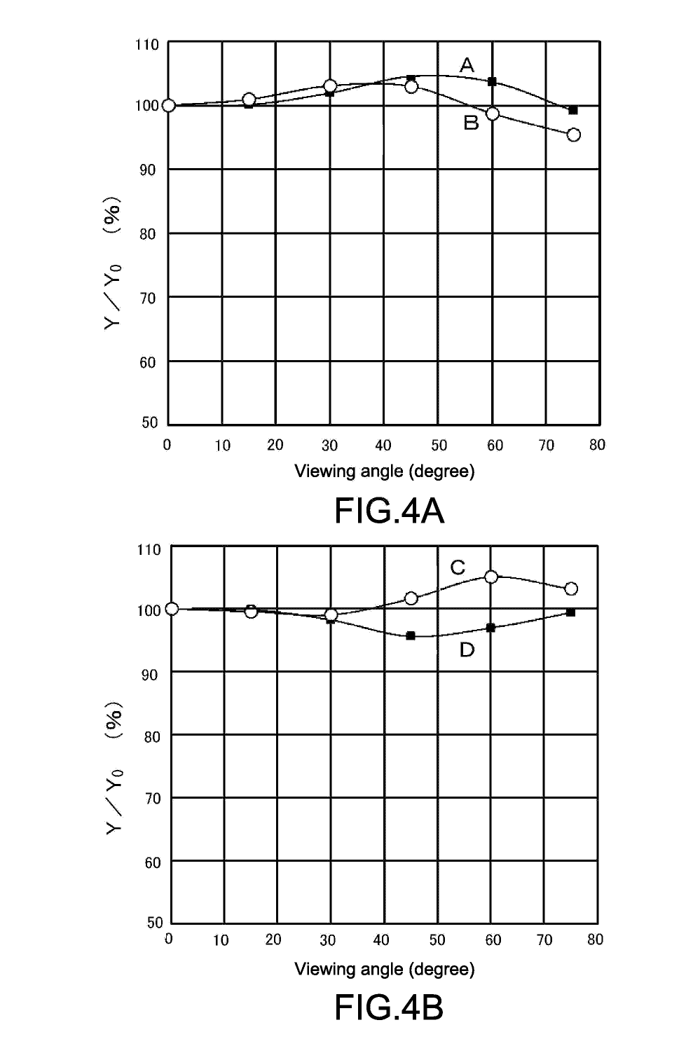

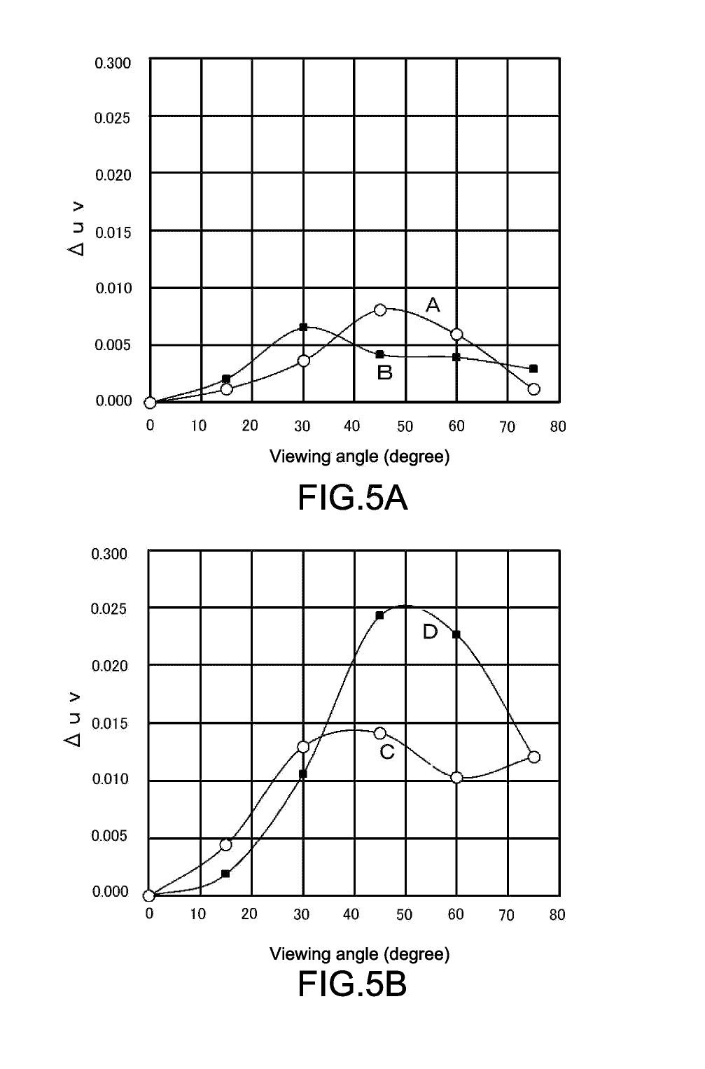

Moreover, in the display apparatuses using the light emitting element according to the example 1 or the comparative example 1, simulation results of change in luminance (Y/Y0) and change in chromaticity (Δuv) obtained by increasing the thickness of the second optical transparent layers 42 and 42′ by 10% with a viewing angle being used as a parameter are shown in FIG. 4A and FIG. 4B, and FIG. 5A and FIG. 5B, respectively. It should be noted that in FIG. 4A, FIG. 4B, FIG. 5A, and FIG. 5B, the curve “A” shows the results with the thickness of the second optical transparent layer 42 being a predetermined value in the display apparatus according to the example 1, the curve “B” shows the results obtained by increasing the thickness (predetermined value) of the second optical transparent layer 42 by 10% in the display apparatus according to the example 1, the curve “C” shows the results with the thickness of the second optical transparent layer 42′ being a predetermined value in the display apparatus according to the comparative example 1, and the curve “D” shows the results obtained by increasing the thickness (predetermined value) of the second optical transparent layer 42′ by 10% in the display apparatus according to the comparative example 1.

It can be seen that from FIG. 4B and FIG. 5B, in the case where the thickness of the second optical transparent layer 42 is a predetermined value, change in luminescence can be maintained to be not less than 85% at the viewing angle of 45 degrees in also the comparative example 1, and change in chromaticity (Δuv) can be not more than 0.015. However, in the case where the thickness (predetermined value) of the second optical transparent layer 42′ is increased by 10%, the luminance is significantly reduced and the chromaticity is largely displaced at the viewing angle of about 45 degrees. On the other hand, in the example 1, the viewing angle dependency of the change in luminance and change in chromaticity is low, the luminance is not significantly reduced and the chromaticity is not largely displaced at the viewing angle of about 45 degrees, even if the thickness (predetermined value) of the second optical transparent layer 42 is increased by 10%, as is clear from FIG. 4A and FIG. 5A. Specifically, in the display apparatus according to the example 1, the decrease in the luminance at the viewing angle of 45 degrees is not more than 30% of the luminance at the viewing angle of 0 degrees, and the value of displacement of chromaticity Δuv at the viewing angle of 45 degrees is not more than 0.015. As described above, the light emitting element according to the example 1 has high tolerance for the thickness variability of the optical transparent layer at the time of production, and therefore it is possible to ensure high productivity.

In the light emitting element according the example 1, the first reflection interface RF₁, the second reflection interface RF₂, the third reflection interface RF₃, and the fourth reflection interface RF₄ constitute a sort of interference filter, and reflection of light from the first luminescent layer on the first reflection interface RF₁ is enhanced and reflection of light from the second luminescent layer on the first reflection interface RF₁ is also enhanced by satisfying the equation (1) and the equation (2). Moreover, by satisfying any one of the equation (3-A), the equation (3-B), the equation (3-C), and the equation (3-D), reflection of light from the first luminescent layer on the third reflection interface RF₃ is enhanced in the case where reflection of light from the first luminescent layer on the second reflection interface RF₂ is reduced. On the other hand, in the case where reflection of light from the first luminescent layer on the second reflection interface RF₂ is enhanced, reflection of light from the first luminescent layer on the third reflection interface RF₃ is weakened. Then, reflection of light from the first luminescent layer on the fourth reflection interface RF₄ is weakened, for example. The order at this time is the same as the order in the reflection on the third reflection interface RF₃, for example. Furthermore, any one of the equation (4-A), the equation (4-B), the equation (4-C), the equation (4-D), the equation (4-E), and the equation (4-F) is satisfied. Specifically, in the case where reflection of light from the second luminescent layer on the second reflection interface RF₂ is weakened, reflection of light from the second luminescent layer on the third reflection interface RF₃ is enhanced. Alternatively, in the case where reflection of light from the second luminescent layer on the second reflection interface RF₂ is enhanced, reflection of light from the second luminescent layer on the third reflection interface RF₃ is weakened. Alternatively, reflection of light from the second luminescent layer on the second reflection interface RF₂ is weakened, and light reflection of light from the second luminescent layer on the third reflection interface RF₃ is weakened.

Then, as described above, by appropriately combining the conditions of enhancing and weakening reflection of light in the interference filter, particularly, by defining the optical distance L₁₄ having the order m₄ that has a predetermined relationship with the order m₃ defining the optical distance L₁₃ in the equation (3-A), the equation (3-B), the equation (3-C), and the equation (3-D) for forming (generating) interference being an antiphase with respect to the high frequency ripple in the interference filter, it is possible to reduce the generation of high frequency ripple on the interference filter. Moreover, by arranging the first reflection interface RF₁, the second reflection interface RF₂, the third reflection interface RF₃, and the fourth reflection interface RF₄, it is possible to obtain an interference filter having a light transmittance curve that is almost flat in a broad wavelength range, to provide a light emitting element that has favorable chromaticity and emits white light, and to significantly reduce the viewing angle dependency of luminance and chromaticity with respect to light of combined colors of two or more different colors in the visible light region significantly. In addition, even if the thickness of the optical transparent layer is changed from the predetermined value, it is possible to provide a display apparatus with very small viewing angle dependency of luminance and chromaticity. Furthermore, because an interference filter having a high light transmittance can be obtained, i.e., the light emission efficiency of the light emitting element can be improved significantly, it is possible to reduce the power consumption of the display apparatus.

### Example 2

An example 2 is a modified example of the example 1. In the example 1, the first luminescent layer 34 includes a different color luminescent layer, but the thickness of the green luminescent layer and the red luminescent layer is made thin such that the light emission center of the different color luminescent layer can be regarded as being at one level. However, in the design of the light emitting element or display apparatus, or based on the production processes, it has no choice but to make the green luminescent layer and the red luminescent layer thick, and it may be impossible to regard the light emission center of the different color luminescent layer as being at one level, in some cases. Specifically, the light emission center of a first color of the different color luminescent layer (the first luminescent layer 34 in the case of the example 2), is apart from the light emission center of a second color of the different color luminescent layer by not less than 5 nm in some cases. Moreover, it has no choice but to change the lamination order of the first color luminescent layer and the second color luminescent layer of the different color luminescent layer depending on the material forming the luminescent layer, for example, and it may be impossible to regard the light emission center of the different color luminescent layer as being at one level, in some cases.

In such a case, for the light emission center of the first color of the first luminescent layer and the light emission center of the second color of the first luminescent layer, various parameters may be determined to satisfy the above-mentioned equation (1), the equation (2), any one of the equation (3-A), the equation (3-B), the equation (3-C), and the equation (3-D), and any one of the equation (4-A), the equation (4-B), the equation (4-C), the equation (4-D), the equation (4-E), and the equation (4-F).

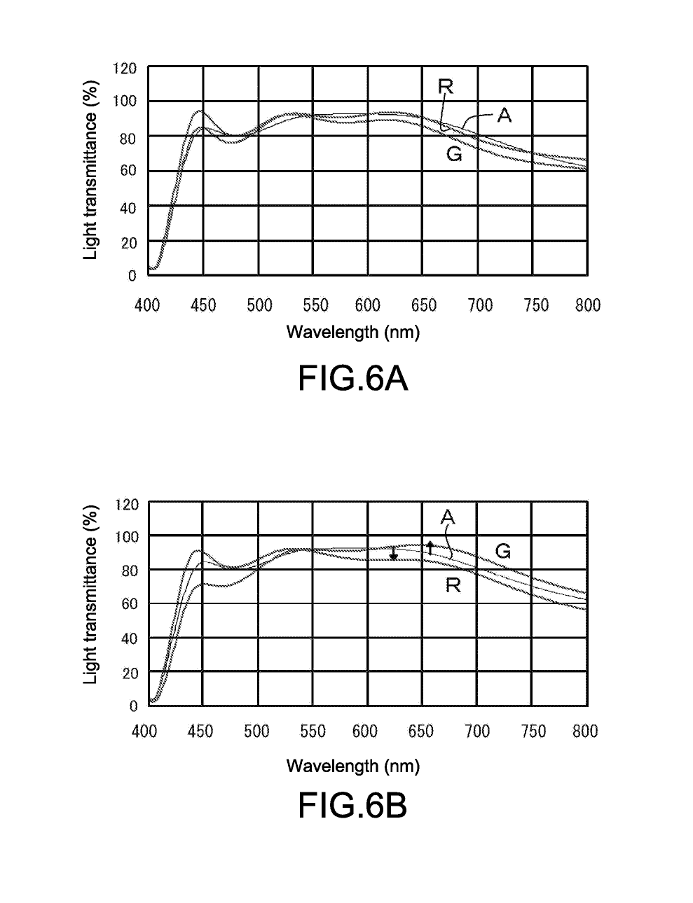

Alternatively, in the case where it may be impossible to regard the light emission center of the different color luminescent layer as being at one level as described above, the fourth optical transparent layer may be further provided. Alternatively, the second reflection interface may include a plurality of interfaces, for example. The results obtained by calculating the light transmittance of the interference filter in the light emitting elements according to the example 2 and the reference example are shown in FIG. 6A and FIG. 6B.

Specifically, in the case where the fourth optical transparent layer is not provided, the first luminescent layer 34 includes two layers of a green luminescent layer and a red luminescent layer from the first electrode side, and the distance between the light emission center of the green luminescent layer and the light emission center of the red luminescent layer is 20 nm (reference example), the light transmittance curve (represented by “G”) of the interference filter with respect to green light from the green luminescent light and the light transmittance curve (represented by “R”) of the interference filter with respect to red light from the red luminescent light are shown in FIG. 6B. It should be noted that in FIG. 6A and FIG. 6B, the light transmittance curve A is a light transmittance curve in the case where the light emission center of the green luminescent layer and the light emission center of the red luminescent layer can be regarded as being at one level. It should be noted that various parameters of a light emitting element in which the light transmittance curve G and the light transmittance curve R of the interference filter are obtained, and a light emitting element in which the light transmittance curve A of the interference filter is obtained are the same as those described in the example 1 (see Table 1). In the wavelength range of about 550 nm to 650 nm, a change with the wavelength of the light transmittance curve G of the interference filter with respect to green light emitted from the green luminescent layer to the outside of the system being used as a variable shows a tendency opposite to that of a change with the wavelength of the light transmittance curve R of the interference filter with respect to red light emitted from the red luminescent layer to the outside of the system being used as a variable. Specifically, the change with the wavelength of the light transmittance curve G being used as a variable has a tendency to increase, while the change with the wavelength of the light transmittance curve R being used as a variable has a tendency to decrease. Therefore, if the viewing angle is large, the proportion of decrease in luminance of the green light is larger than the proportion of decrease in luminance of the red light. As a result, if the viewing angle is large, the displacement of chromaticity is large.

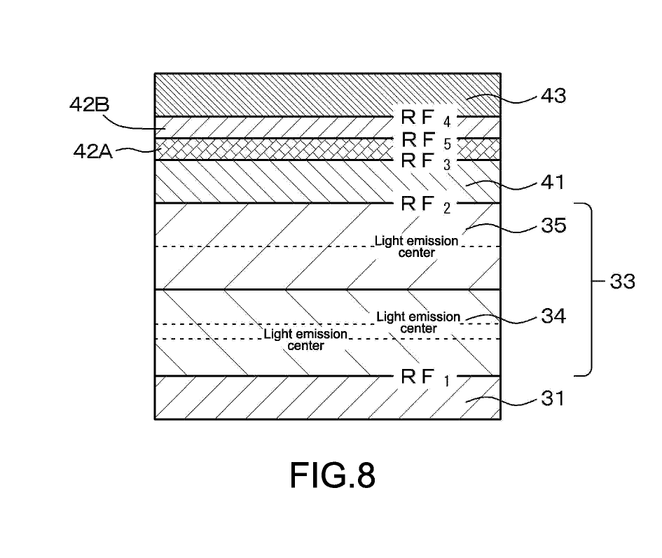

In the light emitting element according to the example 2, as shown in FIG. 8 being a configuration diagram of the layers constituting the light emitting element, the second optical transparent layer 42 is divided into two optical transparent layers (a second optical transparent layer 42A and a second optical transparent layer 42B). Here, the second optical transparent layer 42A corresponds to the fourth optical transparent layer, and the second optical transparent layer 42B corresponds to the second optical transparent layer. The reflection interface formed by the second optical transparent layer 42A and the second optical transparent layer 42B is referred to as “fifth reflection interface RF₅” for the sake of convenience. By the presence of the first optical transparent layer 41, the second optical transparent layer 42A, and the second optical transparent layer 42B, the second reflection interface includes a plurality of interfaces (the third reflection interface RF₃ and the fifth reflection interface RF₅). Here, the fifth reflection interface RF₅ is set under the conditions to enhance reflection of light in the central wavelength (λ₁) in a wavelength range of green light and red light emitted from the first luminescent layer. Specifically, in the case where L₁₅ is assumed to be a mean value of an optical distance from a fifth reflection interface being an interface of the fourth optical transparent layer and the second optical transparent layer to the (two) light emission center(s) of the first luminescent layer, φ₄ is assumed to be a phase change of light when being reflected on the fifth reflection interface, and the equation, λ₁−15≦λ₁₅≦λ₁−15, is satisfied, L₁₅ and m₅ exist such that the equation,

2*L₁₅/λ₁₅+φ₅/2π=m₅+½ (11-1) or

2*L₁₅/λ₁₅+φ₅/2π=m₅ (11-2)

is satisfied.

The light transmittance curve of the obtained interference filter including the first reflection interface RF₁, the second reflection interface RF₂, the third reflection interface RF₃, the fourth reflection interface RF₄, and the fifth reflection interface RF₅ is shown in FIG. 6A. It should be noted that various parameters are set so as to satisfy the above-mentioned equation (11-2). In FIG. 6A, “G” represents the light transmittance curve of the interference filter with respect to green light from the green luminescent layer, and “R” represents the light transmittance curve of the interference filter with respect to red light from the red luminescent layer. The change with the wavelength of the light transmittance curve G of the interference filter with respect to green light emitted from the green luminescent layer to the outside of the system being used as a variable shows the same tendency as that of the change with the wavelength of the light transmittance curve R of the interference filter with respect to red light emitted from the red luminescent layer to the outside of the system being used as a variable. Specifically, the change with the wavelength of the light transmittance curve G being used as a variable shows the same tendency as that of the change with the change with the wavelength of the light transmittance curve R being used as a variable. Therefore, even if the viewing angle is large, the proportion of the decrease in luminance of green light is almost the same as the proportion of the decrease in luminance of red light. Even in the viewing angle is large, the displacement of chromaticity is not large.

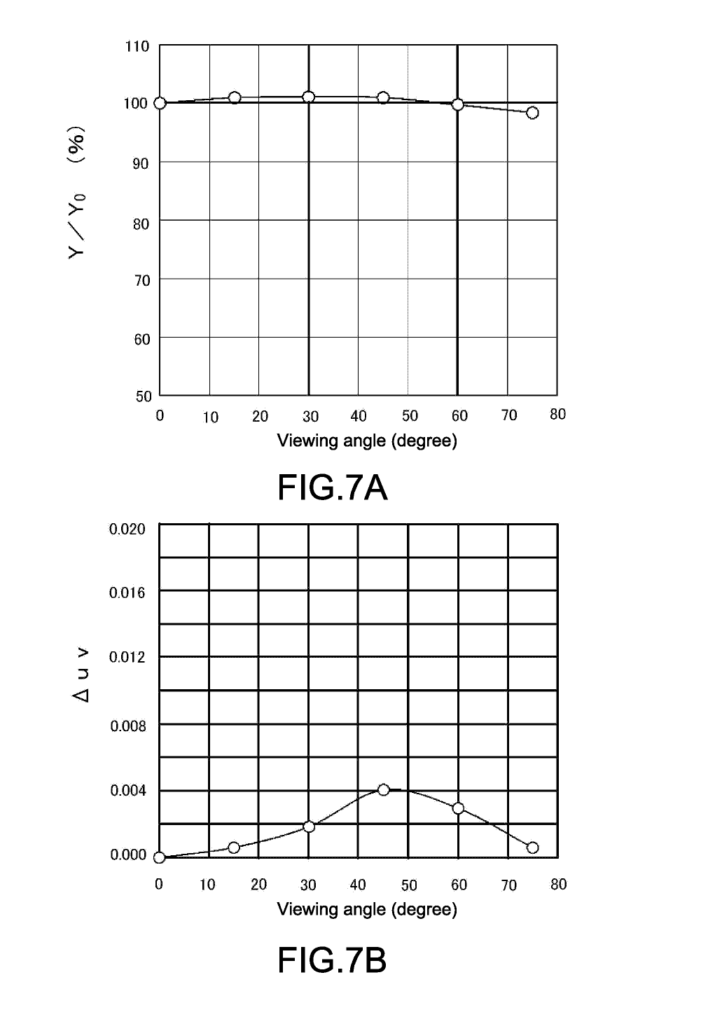

In the display apparatus using the light emitting element according to the example 2, simulation results of change in luminance (Y/Y₀) with a viewing angle being used as a parameter are shown in FIG. 7A, and simulation results of change in chromaticity (Δuv) with a viewing angle being used as a parameter are shown in FIG. 7B. Even if the viewing angle is changed, the change in luminance (Y/Y₀) is almost constant. Moreover, it can be seen that change in chromaticity (Δuv) satisfies the equation, Δuv≦50.004. It should be noted that in the case where two layers of the green luminescent layer and the red luminescent layer are provided from the first electrode side, various parameters are favorably set so as to satisfy the above-mentioned equation (11-2). In the case where two layers of the red luminescent layer and the green luminescent layer are provided from the first electrode side, various parameters are favorably set so as to satisfy the above-mentioned equation (11-1).

### Example 3

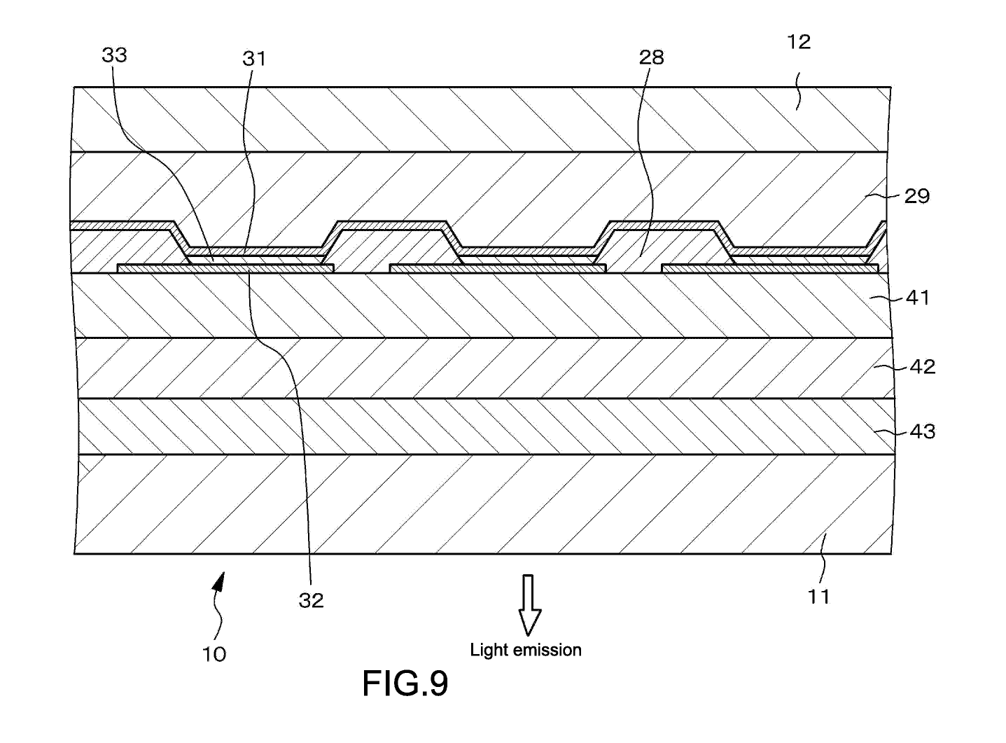

An example 3 is a modified example of the example 1 or the example 2, and relates to a lower surface light emission type display apparatus. As shown in FIG. 9 being a schematic partial cross-sectional view, the light emitting element 10 according to the example 3 is a lower surface light emission type emitting element in which the second electrode 32, the organic layer 33, and the first electrode 31 are laminated on the first substrate 11 in the stated order. Light from the luminescent layer is emitted to the outside via the first substrate 11. It should be noted that although not shown, a transparent conductive material layer having a thickness of not less than 1 μm, a transparent insulating layer having a thickness of not less than 1 μm, a resin layer having a thickness of not less than 1 μm, a glass layer having a thickness of not less than 1 μm, or an air layer having a thickness of not less than 1 μm may be formed on a surface of the third optical transparent layer, which is opposite to the second optical transparent layer, i.e., between the third optical transparent layer 43 and the first substrate 11. The uppermost layer on the upper side of the first electrode 31 is formed by the second substrate 12. The first electrode 31 is connected to the second substrate 12 by an adhesive layer 29.

### Example 4

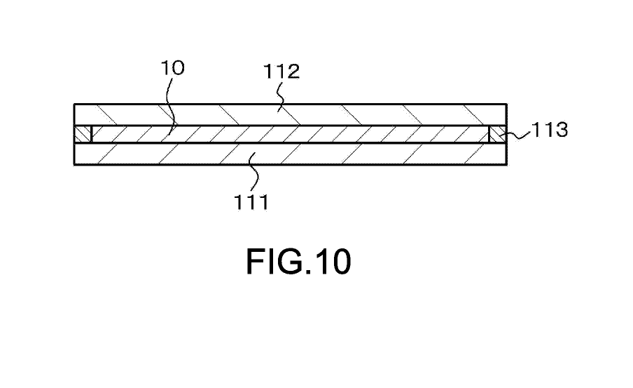

An example 4 relates to a lighting apparatus according to one embodiment of the present disclosure. As shown in FIG. 10 being a schematic cross-sectional view, the light emitting element 10 described in the example 1 to the example 3 is arranged between a transparent first substrate 111 and a second substrate 112, in the lighting apparatus according to the example 4. Depending on the structure of the light emitting element 10, light from the luminescent layer is emitted from the second substrate side or the first substrate side. It should be noted that the outer periphery portion of the first substrate 111 is joined to the outer peripheral portion of the second substrate 112 by a sealing member 113. The planar shape of the lighting apparatus is selected as necessary, and has, for example, a square shape or a rectangular shape. In FIG. 10, although only one light emitting element 10 is shown, a plurality of light emitting elements may be arranged in a desired pattern as necessary. It should be noted that because the lighting apparatus has a well-known configuration and structure, the detailed description thereof will be omitted.

In the lighting apparatus according to the example 4, by using the light emitting element according to the example 1 to the example 3, it is possible to achieve a lighting apparatus with a small angle dependency, i.e., with favorable light distribution properties of an extremely small change in strength or chromaticity depending on the illumination direction (e.g., planar light source apparatus), and to achieve a lighting apparatus with excellent color rendering properties. Moreover, by selecting the light emission color of the light emitting element, it is possible to obtain various light emission colors in addition to white light emission.

Although embodiments of the present disclosure have been described based on preferred examples, the embodiments of the present disclosure are not limited to the above-mentioned examples. The configuration and structure of the light emitting element, the display apparatus, and the lighting apparatus described in the examples are given for exemplary purposes, and various modifications can be made as appropriate.

It should be noted that the present disclosure may also take the following configurations.

### [A01](Light Emitting Element: First Embodiment)

A light emitting element, including:

a first electrode;

a second electrode; and

an organic layer in which a first luminescent layer and a second luminescent layer are provided from a first electrode side, the organic layer being provided between the first electrode and the second electrode, light from the organic layer being reflected on an interface of the luminescent layer and the first electrode, passing through the second electrode, and being emitted to outside, a first optical transparent layer, a second optical transparent layer, and a third optical transparent layer being provided, from a second luminescent layer side, on a side of the second luminescent layer, the side being opposite to the first luminescent layer, the light emitting element satisfying an equation (1), an equation (2), one of an equation (3-A), equation (3-B), an equation (3-C), and an equation (3-D), and one of an equation (4-A), an equation (4-B), an equation (4-C), an equation (4-D), an equation (4-E), and an equation (4-F),

$$\begin{matrix}( - {φ}_{1} / 2 π + {m}_{1} ) \cdot ( {λ}_{1} - 150 ) / 2 \leq {L}_{11} \leq ( - {φ}_{1} / 2 π + {m}_{1} ) \cdot ( {λ}_{1} + 80 ) / 2 & ( 1 ) \\ ( - {φ}_{1} / 2 π + {n}_{1} ) \cdot ( {λ}_{2} - 150 ) / 2 \leq {L}_{21} \leq ( - {φ}_{1} / 2 π + {n}_{1} ) \cdot ( {λ}_{2} + 80 ) / 2 & ( 2 ) \\ {L}_{12} \leq ( - {φ}_{2} / 2 π + {m}_{2} + 1 / 2 ) \cdot ( {λ}_{1} - 15 ) / 2 , \\ ( - {φ}_{3} / 2 π + {m}_{3} ) \cdot ( {λ}_{1} + 15 ) / 2 \leq {L}_{13} , and \\ ( - {φ}_{4} / 2 π + {m}_{4} + 1 / 2 ) \cdot ( {λ}_{1} - 150 ) / 2 \leq {L}_{14} \leq ( - {φ}_{4} / 2 π + {m}_{4} + 1 / 2 ) \cdot ( {λ}_{1} + 80 ) / 2 & ( 3 \text{-} A ) \\ {L}_{12} \leq ( - {φ}_{2} / 2 π + {m}_{2} ) \cdot ( {λ}_{1} - 15 ) / 2 , \\ ( - \text{?} / 2 π + {m}_{3} + 1 / 2 ) \cdot ( {λ}_{1} + 15 ) / 2 \leq \text{?} , and \\ ( - {φ}_{4} / 2 π + {m}_{4} + 1 / 2 ) \cdot ( {λ}_{1} - 150 ) / 2 \leq {L}_{13} \leq ( - {φ}_{4} / 2 π + {m}_{4} + 1 / 2 ) \cdot ( {λ}_{1} + 80 ) / 2 & ( 3 \text{-} B ) \\ ( - {φ}_{2} / 2 π + {m}_{2} + 1 / 2 ) \cdot ( {λ}_{1} + 15 ) / 2 \leq {L}_{12} , \\ {L}_{13} \leq ( - {φ}_{2} / 2 π + {m}_{3} ) \cdot ( {λ}_{1} - 15 ) / 2 , and \\ ( - {φ}_{4} / 2 π + {m}_{4} + 1 / 2 ) \cdot ( {λ}_{1} - 150 ) / 2 \leq {L}_{14} \leq ( - {φ}_{4} / 2 π + {m}_{4} + 1 / 2 ) \cdot ( {λ}_{1} + 80 ) / 2 & ( 3 \text{-} C ) \\ ( - \text{?} / 2 π + {m}_{2} ) \cdot ( {λ}_{1} + 15 ) / 2 \leq {L}_{12} , \\ {L}_{13} \leq ( - {φ}_{3} / 2 π + {m}_{3} + 1 / 2 ) \cdot ( {λ}_{1} - 15 ) / 2 , and \\ ( - {φ}_{4} / 2 π + {m}_{4} + 1 / 2 ) \cdot ( {λ}_{1} - 150 ) / 2 \leq \text{?} \leq ( - {φ}_{4} / 2 π + {m}_{4} + 1 / 2 ) \cdot ( {λ}_{1} + 80 ) / 2 & ( 3 \text{-} D ) \\ \text{?} \leq ( - {φ}_{2} / 2 π + \text{?} + 1 / 2 ) \cdot ( {λ}_{2} - 15 ) / 2 , and \\ ( - \text{?} / 2 π + {n}_{3} ) \cdot ( {λ}_{2} + 15 ) / 2 \leq \text{?} & ( 4 \text{-} A ) \\ \text{?} \leq ( - {φ}_{2} / 2 π + \text{?} ) \cdot ( {λ}_{2} - 15 ) / 2 , and \\ ( - \text{?} / 2 π + {n}_{3} + 1 / 2 ) \cdot ( {λ}_{2} + 15 ) / 2 \leq \text{?} & ( 4 \text{-} B ) \\ \text{?} \leq ( - {φ}_{2} / 2 π + \text{?} + 1 / 2 ) \cdot ( {λ}_{2} - 15 ) / 2 , and \\ ( - \text{?} / 2 π + {n}_{3} + 1 / 2 ) \cdot ( {λ}_{2} + 15 ) / 2 \leq \text{?} & ( 4 \text{-} C ) \\ ( - {φ}_{2} / 2 π + {n}_{2} + 1 / 2 ) \cdot ( {λ}_{2} + 15 ) / 2 \leq \text{?} , and \\ \text{?} \leq ( - {φ}_{3} / 2 π + {n}_{3} ) \cdot ( {λ}_{2} - 15 ) / 2 & ( 4 \text{-} D ) \\ ( - {φ}_{1} / 2 π + {n}_{2} ) \cdot ( {λ}_{2} + 15 ) / 2 \leq \text{?} , and \\ \text{?} \leq ( - \text{?} / 2 π + {n}_{3} + 1 / 2 ) \cdot ( {λ}_{2} - 15 ) / 2 & ( 4 \text{-} E ) \\ ( - {φ}_{2} / 2 π + {n}_{2} + 1 / 2 ) \cdot ( {λ}_{2} + 15 ) / 2 \leq \text{?} , and \\ \text{?} \leq ( - \text{?} / 2 π + {n}_{3} + 1 / 2 ) \cdot ( {λ}_{2} - 15 ) / 2 \\ \text{?} \text{indicates text missing or illegible when filed} & ( 4 \text{-} F )\end{matrix}$$

where
λ₁ represents a central wavelength in a wavelength range of light emission in the first luminescent layer (unit: nm),
λ₂ represents a central wavelength in a wavelength range of light emission in the second luminescent layer (unit: nm),
L₁₁ represents an optical distance from a first reflection interface being an interface of the first luminescent layer and the first electrode to a light emission center of the first luminescent layer (unit: nm),
L₁₂ represents an optical distance from a second reflection interface being an interface of the second luminescent layer and the first optical transparent layer to the light emission center of the first luminescent layer (unit: nm),
L₁₃ represents an optical distance from a third reflection interface being an interface of the first optical transparent layer and the second optical transparent layer to the light emission center of the first luminescent layer (unit: nm),
L₁₄ represents an optical distance from a fourth reflection interface being an interface of the second optical transparent layer and the third optical transparent layer to the light emission center of the first luminescent layer (unit: nm),
L₂₁ represents an optical distance from the first reflection interface to a light emission center of the second luminescent layer (unit: nm),
L₂₂ represents an optical distance from the second reflection interface to the light emission center of the second luminescent layer (unit: nm),
L₂₃ represents an optical distance from the third reflection interface to a light emission center of the second luminescent layer (unit: nm),
φ₁ represents a phase change of light reflected on the first reflection interface (unit: radian),
φ₂ represents a phase change of light reflected on the second reflection interface (unit: radian),
φ₃ represents a phase change of light reflected on the third reflection interface (unit: radian),
φ₄ represents a phase change of light reflected on the fourth reflection interface (unit: radian),
m₁ is an integer of not less than 0,
n₁ is an integer of not less than 0,
m₂, m₃, n₂, and n₃ are integers, and
m₄=m₃, m₃+1, or m₃−1.
[A02] The light emitting element according to [A01], in which
m₁=0 and n₁=1.
   [A03] The light emitting element according to [A01] or [A02], in which

the first reflection interface, the second reflection interface, the third reflection interface, and the fourth reflection interface constitute an interference filter.

[A04] The light emitting element according to any one of [A01] to [A03], in which

a difference between a refractive index of the organic layer and a refractive index of the first optical transparent layer is not less than 0.15, a difference between the refractive index of the first optical transparent layer and a refractive index of the second optical transparent layer is not less than 0.15, and a difference between the refractive index of the second optical transparent layer and a refractive index of the third optical transparent layer is not less than 0.15.

[A05] The light emitting element according to any one of [A01] to [A04], in which

an optical thickness t₂ of the second optical transparent layer satisfies an equation, 0.2*λ₁≦t₂≦0.34*λ₁.

[A06] The light emitting element according to any one of [A01] to [A05], in which

a decrease in luminance at a viewing angle of 45 degrees is not more than 30% of luminance at a viewing angle of 0 degrees.

[A07] The light emitting element according to any one of [A01] to [A06], in which

a value of displacement of chromaticity Δuv at a viewing angle of 45 degrees is not more than 0.015.

[A08] The light emitting element according to any one of [A01] to [A07], in which

a metal layer having a thickness of not more than 5 nm is provided between the second luminescent layer and the first optical transparent layer.

[A09] The light emitting element according to any one of [A01] to [A08], in which

one of the second reflection interface, the third reflection interface, and the fourth reflection interface includes a plurality of interfaces.

[A10] The light emitting element according to any one of [A01] to [A09], in which

at least one of the first luminescent layer and the second luminescent layer is formed of a different color luminescent layer that emits light of two or more different colors, the light emitting element further including a fourth optical transparent layer in a case where a light emission center of the different color luminescent layer is not regarded as being at one level.

[A11] The light emitting element according to [A10], in which

the first reflection interface being an interface of the first luminescent layer and the first electrode, the second reflection interface including the second luminescent layer, the first optical transparent layer, the second optical transparent layer, the third optical transparent layer, and the fourth optical transparent layer, the third reflection interface, the fourth reflection interface, and the fifth reflection interface constitute an interference filter, and

a change with a wavelength of a light transmittance curve of the interference filter with respect to light emitted from the different color luminescent layer to outside of a system being used as a variable shows the same tendency as a wavelength of a light transmittance curve of the interference filter with respect to different light emitted from the different color luminescent layer to outside of the system being used as a variable.

[A12] The light emitting element according to any one of [A01] to [A11], in which

the first electrode, the organic layer, and the second electrode are laminated on a substrate in the stated order.

[A13] The light emitting element according to [A12], in which

one of a transparent conductive material layer, a transparent insulating layer, a resin layer, a glass layer, and an air layer, which has a thickness of not less than 0.5 μm, is further formed on a surface of the third optical transparent layer, the surface being opposite to the second optical transparent layer.

[A14] The light emitting element according to any one of [A01] to [A11], in which

the second electrode, the organic layer, and the first electrode are laminated on a substrate in the stated order.

[A15] The light emitting element according to [A14], in which

one of a transparent conductive material layer, a transparent insulating layer, a resin layer, a glass layer, and an air layer, which has a thickness of not less than 1 μm, is further formed a surface of the third optical transparent layer, the surface being opposite to the second optical transparent layer.

### [B01](Light Emitting Element: Second Embodiment)

A light emitting element, including:

a first electrode;

a second electrode; and

an organic layer in which a first luminescent layer and a second luminescent layer are provided from a first electrode side, the organic layer being provided between the first electrode and the second electrode, light from the organic layer being reflected on a first reflection interface including the luminescent layer and the first electrode, passing through the second electrode, and being emitted to outside, a first optical transparent layer, a second optical transparent layer, and a third optical transparent layer being provided, from a second luminescent layer side, on a side of the second luminescent layer, the side being opposite to the first luminescent layer, the first optical transparent layer on a second luminescent layer side constituting a second reflection interface, the first optical transparent layer and the second optical transparent layer constituting a third reflection interface, the second optical transparent layer and the third optical transparent layer constituting a fourth reflection interface, the first reflection interface, the second reflection interface, the third reflection interface, and the fourth reflection interface constituting an interference filter, the first reflection interface being arranged to the following (condition-1), the second reflection interface, the third reflection interface, and the fourth reflection interface are arranged to satisfy one of a (condition-2A) and a (condition-2B), the second reflection interface and the third reflection interface being arranged to satisfy one of a (condition-3A), a (condition-3B), and a (condition-3C),

### (Condition-1)

reflection of light from the first luminescent layer on the first reflection interface is enhanced and reflection of light from the second luminescent layer on the first reflection interface is enhanced,

### (Condition-2A)

reflection of light from the first luminescent layer on the second reflection interface is weakened, reflection of light from the first luminescent layer on the third reflection interface is enhanced, and reflection of light from the first luminescent layer on the fourth reflection interface is weakened with one of the same order as an order of reflection of light from the first luminescent layer on the third reflection interface is enhanced, an order lower than the order of reflection, and an order higher than the order of reflection,

### (Condition-2B)

reflection of light from the first luminescent layer on the second reflection interface is enhanced, reflection of light from the first luminescent layer on the third reflection interface is weakened, reflection of light from the first luminescent layer on the fourth reflection interface is weakened with one of the same order as an order of reflection of light from the first luminescent layer on the fourth reflection interface is enhanced, an order lower than the order of reflection, and an order higher than the order of reflection,

### (Condition-3A)

reflection of light from the second luminescent layer on the second reflection interface is weakened, and reflection of light from the second luminescent layer on the third reflection interface is enhanced,

### (Condition-3B)

reflection of light from the second luminescent layer on the second reflection interface is enhanced, and reflection of light from the second luminescent layer on the third reflection interface is weakened,

### (Condition-3C)

reflection of light from the second luminescent layer on the second reflection interface is weakened, and reflection of light from the second luminescent layer on the third reflection interface is weakened.
[B02] The light emitting element according to [B01], in which

a position of the second reflection interface is determined such that a peak position of a light transmittance of the interference filter is displaced from a peak position of light emission spectrum of light from the first luminescent layer and a peak position of light emission spectrum of light from the second luminescent layer.

[B03] The light emitting element according to [B01] or [B02], in which

a position of the third reflection interface is determined such that a peak position of a light transmittance of the interference filter is displaced from a peak position of light emission spectrum of light from the first luminescent layer and a peak position of light emission spectrum of light from the second luminescent layer.

[B04] The light emitting element according to any one of [B01] to [B03], in which

a difference between a refractive index of the organic layer and a refractive index of the first optical transparent layer is not less than 0.15, a difference between the refractive index of the first optical transparent layer and a refractive index of the second optical transparent layer is not less than 0.15, and a difference between the refractive index of the second optical transparent layer and a refractive index of the third optical transparent layer is not less than 0.15.

[B05] The light emitting element according to any one of [B01] to [B04], in which

a decrease in luminance at a viewing angle of 45 degrees is not more than 30% of luminance at a viewing angle of 0 degrees.

[B06] The light emitting element according to any one of [B01] to [B05], in which

a value of displacement of chromaticity Δuv at a viewing angle of 45 degrees is not more than 0.015.

[B07] The light emitting element according to any one of [B01] to [B06], in which

a metal layer having a thickness of not more than 5 nm is provided between the second luminescent layer and the first optical transparent layer.

[B08] The light emitting element according to any one of [B01] to [B07], in which

one of the second reflection interface, the third reflection interface, and the fourth reflection interface includes a plurality of interfaces.

[B09] The light emitting element according to any one of [B01] to [B08], in which

at least one of the first luminescent layer and the second luminescent layer is formed of a different color luminescent layer that emits light of two or more different colors, the light emitting element further including a fourth optical transparent layer in a case where a light emission center of the different color luminescent layer is not regarded as being at one level.

[B10] The light emitting element according to [B09], in which

the first reflection interface being an interface of the first luminescent layer and the first electrode, the second reflection interface including the second luminescent layer, the first optical transparent layer, the second optical transparent layer, the third optical transparent layer, and the fourth optical transparent layer, the third reflection interface, the fourth reflection interface, and the fifth reflection interface constitute an interference filter, and

a change with a wavelength of a light transmittance curve of the interference filter with respect to light emitted from the different color luminescent layer to outside of a system being used as a variable shows the same tendency as a wavelength of a light transmittance curve of the interference filter with respect to different light emitted from the different color luminescent layer to outside of the system being used as a variable.

[B11] The light emitting element according to any one of [B01] to [B10], in which

the first electrode, the organic layer, and the second electrode are laminated on a substrate in the stated order.

[B12] The light emitting element according to [B11], in which

one of a transparent conductive material layer, a transparent insulating layer, a resin layer, a glass layer, and an air layer, which has a thickness of not less than 0.5 μm, is further formed on a surface of the third optical transparent layer, the surface being opposite to the second optical transparent layer.

[B13] The light emitting element according to any one of [B01] to [B10], in which

the second electrode, the organic layer, and the first electrode are laminated on a substrate in the stated order.

[B14] The light emitting element according to [B13], in which

one of a transparent conductive material layer, a transparent insulating layer, a resin layer, a glass layer, and an air layer, which has a thickness of not less than 1 μm, is further formed a surface of the third optical transparent layer, the surface being opposite to the second optical transparent layer.

### [C01](Display Apparatus)

A display apparatus including

the light emitting elements according to [A01] to [B14] arranged in a two-dimensional matrix pattern.

### [C02](Lighting Apparatus)

A lighting apparatus including

the light emitting element according to [A01] to [B14].

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A light emitting element, comprising:
a first electrode;
a second electrode; and
an organic layer in which a first luminescent layer and a second luminescent layer are provided from a first electrode side, the organic layer being provided between the first electrode and the second electrode, light from the organic layer being reflected on an interface of the luminescent layer and the first electrode, passing through the second electrode, and being emitted to outside, a first optical transparent layer, a second optical transparent layer, and a third optical transparent layer being provided, from a second luminescent layer side, on a side of the second luminescent layer, the side being opposite to the first luminescent layer, the light emitting element satisfying an equation (1), an equation (2), one of an equation (3-A), equation (3-B), an equation (3-C), and an equation (3-D), and one of an equation (4-A), an equation (4-B), an equation (4-C), an equation (4-D), an equation (4-E), and an equation (4-F),
$$\begin{matrix}( - {φ}_{1} / 2 π + {m}_{1} ) \cdot ( {λ}_{1} - 150 ) / 2 \leq {L}_{11} \leq ( - {φ}_{1} / 2 π + {m}_{1} ) \cdot ( {λ}_{1} + 80 ) / 2 & ( 1 ) \\ ( - {φ}_{1} / 2 π + {n}_{1} ) \cdot ( {λ}_{2} - 150 ) / 2 \leq {L}_{21} \leq ( - {φ}_{1} / 2 π + {n}_{1} ) \cdot ( {λ}_{2} + 80 ) / 2 & ( 2 ) \\ {L}_{12} \leq ( - {φ}_{2} / 2 π + {m}_{2} + 1 / 2 ) \cdot ( {λ}_{1} - 15 ) / 2 , \\ ( - {φ}_{3} / 2 π + {m}_{3} ) \cdot ( {λ}_{1} + 15 ) / 2 \leq {L}_{13} , and \\ ( - {φ}_{4} / 2 π + {m}_{4} + 1 / 2 ) \cdot ( {λ}_{1} - 150 ) / 2 \leq {L}_{14} \leq ( - {φ}_{4} / 2 π + {m}_{4} + 1 / 2 ) \cdot ( {λ}_{1} + 80 ) / 2 & ( 3 \text{-} A ) \\ {L}_{12} \leq ( - {φ}_{2} / 2 π + {m}_{2} ) \cdot ( {λ}_{1} - 15 ) / 2 , \\ ( - \text{?} / 2 π + {m}_{3} + 1 / 2 ) \cdot ( {λ}_{1} + 15 ) / 2 \leq \text{?} , and \\ ( - {φ}_{4} / 2 π + {m}_{4} + 1 / 2 ) \cdot ( {λ}_{1} - 150 ) / 2 \leq {L}_{13} \leq ( - {φ}_{4} / 2 π + {m}_{4} + 1 / 2 ) \cdot ( {λ}_{1} + 80 ) / 2 & ( 3 \text{-} B ) \\ ( - {φ}_{2} / 2 π + {m}_{2} + 1 / 2 ) \cdot ( {λ}_{1} + 15 ) / 2 \leq {L}_{12} , \\ {L}_{13} \leq ( - {φ}_{2} / 2 π + {m}_{3} ) \cdot ( {λ}_{1} - 15 ) / 2 , and \\ ( - {φ}_{4} / 2 π + {m}_{4} + 1 / 2 ) \cdot ( {λ}_{1} - 150 ) / 2 \leq {L}_{14} \leq ( - {φ}_{4} / 2 π + {m}_{4} + 1 / 2 ) \cdot ( {λ}_{1} + 80 ) / 2 & ( 3 \text{-} C ) \\ ( - \text{?} / 2 π + {m}_{2} ) \cdot ( {λ}_{1} + 15 ) / 2 \leq {L}_{12} , \\ {L}_{13} \leq ( - {φ}_{3} / 2 π + {m}_{3} + 1 / 2 ) \cdot ( {λ}_{1} - 15 ) / 2 , and \\ ( - {φ}_{4} / 2 π + {m}_{4} + 1 / 2 ) \cdot ( {λ}_{1} - 150 ) / 2 \leq \text{?} \leq ( - {φ}_{4} / 2 π + {m}_{4} + 1 / 2 ) \cdot ( {λ}_{1} + 80 ) / 2 & ( 3 \text{-} D ) \\ \text{?} \leq ( - {φ}_{2} / 2 π + \text{?} + 1 / 2 ) \cdot ( {λ}_{2} - 15 ) / 2 , and \\ ( - \text{?} / 2 π + {n}_{3} ) \cdot ( {λ}_{2} + 15 ) / 2 \leq \text{?} & ( 4 \text{-} A ) \\ \text{?} \leq ( - {φ}_{2} / 2 π + \text{?} ) \cdot ( {λ}_{2} - 15 ) / 2 , and \\ ( - \text{?} / 2 π + {n}_{3} + 1 / 2 ) \cdot ( {λ}_{2} + 15 ) / 2 \leq \text{?} & ( 4 \text{-} B ) \\ \text{?} \leq ( - {φ}_{2} / 2 π + \text{?} + 1 / 2 ) \cdot ( {λ}_{2} - 15 ) / 2 , and \\ ( - \text{?} / 2 π + {n}_{3} + 1 / 2 ) \cdot ( {λ}_{2} + 15 ) / 2 \leq \text{?} & ( 4 \text{-} C ) \\ ( - {φ}_{2} / 2 π + {n}_{2} + 1 / 2 ) \cdot ( {λ}_{2} + 15 ) / 2 \leq \text{?} , and \\ \text{?} \leq ( - {φ}_{3} / 2 π + {n}_{3} ) \cdot ( {λ}_{2} - 15 ) / 2 & ( 4 \text{-} D ) \\ ( - {φ}_{1} / 2 π + {n}_{2} ) \cdot ( {λ}_{2} + 15 ) / 2 \leq \text{?} , and \\ \text{?} \leq ( - \text{?} / 2 π + {n}_{3} + 1 / 2 ) \cdot ( {λ}_{2} - 15 ) / 2 & ( 4 \text{-} E ) \\ ( - {φ}_{2} / 2 π + {n}_{2} + 1 / 2 ) \cdot ( {λ}_{2} + 15 ) / 2 \leq \text{?} , and \\ \text{?} \leq ( - \text{?} / 2 π + {n}_{3} + 1 / 2 ) \cdot ( {λ}_{2} - 15 ) / 2 \\ \text{?} \text{indicates text missing or illegible when filed} & ( 4 \text{-} F )\end{matrix}$$
where
λ1 represents a central wavelength in a wavelength range of light emission in the first luminescent layer (unit: nm),
λ2 represents a central wavelength in a wavelength range of light emission in the second luminescent layer (unit: nm),
L11 represents an optical distance from a first reflection interface being an interface of the first luminescent layer and the first electrode to a light emission center of the first luminescent layer (unit: nm),
L12 represents an optical distance from a second reflection interface being an interface of the second luminescent layer and the first optical transparent layer to the light emission center of the first luminescent layer (unit: nm),
L13 represents an optical distance from a third reflection interface being an interface of the first optical transparent layer and the second optical transparent layer to the light emission center of the first luminescent layer (unit: nm),
L14 represents an optical distance from a fourth reflection interface being an interface of the second optical transparent layer and the third optical transparent layer to the light emission center of the first luminescent layer (unit: nm),
L21 represents an optical distance from the first reflection interface to a light emission center of the second luminescent layer (unit: nm),
L22 represents an optical distance from the second reflection interface to the light emission center of the second luminescent layer (unit: nm),
L23 represents an optical distance from the third reflection interface to a light emission center of the second luminescent layer (unit: nm),
φ1 represents a phase change of light reflected on the first reflection interface (unit: radian),
φ2 represents a phase change of light reflected on the second reflection interface (unit: radian),
φ3 represents a phase change of light reflected on the third reflection interface (unit: radian),
φ4 represents a phase change of light reflected on the fourth reflection interface (unit: radian),
m1 is an integer of not less than 0,
n1 is an integer of not less than 0,
m2, m3, n2, and n3 are integers, and
m4=m3, m3+1, or m3−1.

2. The light emitting element according to claim 1, wherein
the first reflection interface, the second reflection interface, the third reflection interface, and the fourth reflection interface constitute an interference filter.

3. The light emitting element according to claim 1, wherein
an optical thickness t2 of the second optical transparent layer satisfies an equation, 0.2*λ1≦t2≦0.34*λ1.

4. The light emitting element according to claim 1, wherein
a decrease in luminance at a viewing angle of 45 degrees is not more than 30% of luminance at a viewing angle of 0 degrees.

5. The light emitting element according to claim 1, wherein
a value of displacement of chromaticity Δuv at a viewing angle of 45 degrees is not more than 0.015.

6. The light emitting element according to claim 1, wherein
a metal layer having a thickness of not more than 5 nm is provided between the second luminescent layer and the first optical transparent layer.

7. The light emitting element according to claim 1, wherein
one of the second reflection interface, the third reflection interface, and the fourth reflection interface includes a plurality of interfaces.

8. The light emitting element according to claim 1, wherein
at least one of the first luminescent layer and the second luminescent layer is formed of a different color luminescent layer that emits light of two or more different colors, the light emitting element further comprising a fourth optical transparent layer in a case where a light emission center of the different color luminescent layer is not regarded as being at one level.

9. The light emitting element according to claim 8, wherein
the first reflection interface being an interface of the first luminescent layer and the first electrode, the second reflection interface including the second luminescent layer, the first optical transparent layer, the second optical transparent layer, the third optical transparent layer, and the fourth optical transparent layer, the third reflection interface, the fourth reflection interface, and the fifth reflection interface constitute an interference filter, and
a change with a wavelength of a light transmittance curve of the interference filter with respect to light emitted from the different color luminescent layer to outside of a system being used as a variable shows the same tendency as a wavelength of a light transmittance curve of the interference filter with respect to different light emitted from the different color luminescent layer to outside of the system being used as a variable.

10. The light emitting element according to claim 1, wherein
the first electrode, the organic layer, and the second electrode are laminated on a substrate in the stated order.

11. The light emitting element according to claim 10, wherein
one of a transparent conductive material layer, a transparent insulating layer, a resin layer, a glass layer, and an air layer, which has a thickness of not less than 0.5 μm, is further formed on a surface of the third optical transparent layer, the surface being opposite to the second optical transparent layer.

12. The light emitting element according to claim 1, wherein
the second electrode, the organic layer, and the first electrode are laminated on a substrate in the stated order.

13. The light emitting element according to claim 12, wherein
one of a transparent conductive material layer, a transparent insulating layer, a resin layer, a glass layer, and an air layer, which has a thickness of not less than 1 μm, is further formed a surface of the third optical transparent layer, the surface being opposite to the second optical transparent layer.

14. A light emitting element, comprising:
a first electrode;
a second electrode; and
an organic layer in which a first luminescent layer and a second luminescent layer are provided from a first electrode side, the organic layer being provided between the first electrode and the second electrode, light from the organic layer being reflected on a first reflection interface including the luminescent layer and the first electrode, passing through the second electrode, and being emitted to outside, a first optical transparent layer, a second optical transparent layer, and a third optical transparent layer being provided, from a second luminescent layer side, on a side of the second luminescent layer, the side being opposite to the first luminescent layer, the first optical transparent layer on a second luminescent layer side constituting a second reflection interface, the first optical transparent layer and the second optical transparent layer constituting a third reflection interface, the second optical transparent layer and the third optical transparent layer constituting a fourth reflection interface, the first reflection interface, the second reflection interface, the third reflection interface, and the fourth reflection interface constituting an interference filter, the first reflection interface being arranged to the following (condition-1), the second reflection interface, the third reflection interface, and the fourth reflection interface are arranged to satisfy one of a (condition-2A) and a (condition-2B), the second reflection interface and the third reflection interface being arranged to satisfy one of a (condition-3A), a (condition-3B), and a (condition-3C),
(condition-1)
reflection of light from the first luminescent layer on the first reflection interface is enhanced and reflection of light from the second luminescent layer on the first reflection interface is enhanced,
(condition-2A)
reflection of light from the first luminescent layer on the second reflection interface is weakened, reflection of light from the first luminescent layer on the third reflection interface is enhanced, and reflection of light from the first luminescent layer on the fourth reflection interface is weakened with one of the same order as an order of reflection of light from the first luminescent layer on the third reflection interface is enhanced, an order lower than the order of reflection, and an order higher than the order of reflection,
(condition-2B)
reflection of light from the first luminescent layer on the second reflection interface is enhanced, reflection of light from the first luminescent layer on the third reflection interface is weakened, reflection of light from the first luminescent layer on the fourth reflection interface is weakened with one of the same order as an order of reflection of light from the first luminescent layer on the fourth reflection interface is enhanced, an order lower than the order of reflection, and an order higher than the order of reflection,
(condition-3A)
reflection of light from the second luminescent layer on the second reflection interface is weakened, and reflection of light from the second luminescent layer on the third reflection interface is enhanced,
(condition-3B)
reflection of light from the second luminescent layer on the second reflection interface is enhanced, and reflection of light from the second luminescent layer on the third reflection interface is weakened,
(condition-3C)
reflection of light from the second luminescent layer on the second reflection interface is weakened, and reflection of light from the second luminescent layer on the third reflection interface is weakened.

15. The light emitting element according to claim 14, wherein
a position of the second reflection interface is determined such that a peak position of a light transmittance of the interference filter is displaced from a peak position of light emission spectrum of light from the first luminescent layer and a peak position of light emission spectrum of light from the second luminescent layer.

16. The light emitting element according to claim 14, wherein
a position of the third reflection interface is determined such that a peak position of a light transmittance of the interference filter is displaced from a peak position of light emission spectrum of light from the first luminescent layer and a peak position of light emission spectrum of light from the second luminescent layer.

17. A display apparatus comprising
the light emitting elements according to claim 1 arranged in a two-dimensional matrix pattern.

18. A lighting apparatus comprising
the light emitting element according to claim 1.
